(19) United States
(12) Patent Application Publication
(10) Pub. No.: US 2025/0245404 A1
(43) Pub. Date: Jul. 31, 2025

(54) MACHINE-LEARNING-BASED SYSTEM AND METHOD FOR DETERMINING ATOMIC STRUCTURE FROM IMAGES OF SPECTRAL FUNCTIONS

(71) Applicant: The Regents of the University of Colorado, a body corporate, Denver, CO (US)

(72) Inventors: Sanghamitra Neogi, Boulder, CO (US); Artem Konstantionovich Pimachev, Boulder, CO (US)

(21) Appl. No.: 19/043,236

(22) Filed: Jan. 31, 2025

Related U.S. Application Data
(60) Provisional application No. 63/627,297, filed on Jan. 31, 2024.

(51) Int. Cl. G06F 30/27; G06T 17/00

(52) U.S. Cl. CPC G06F 30/27; G06T 17/00

(57) ABSTRACT

A method for determining atomic structure uses a reverse machine-learning model (MLM) that is trained to transform images of spectral functions into atomic descriptors that describe a semiconductor heterostructure, superlattice, or bulk material. The method includes feeding, into a trained machine-learning model, an image of a spectral function of a semiconductor heterostructure. The trained machine-learning model, in response to being fed the image, outputs a set of atomic descriptors for one atom of a plurality of atoms forming a supercell of the semiconductor heterostructure. The set of atomic descriptors include an elemental descriptor that identifies an element type of the one atom. The set of atomic descriptors also include structural descriptors, each of which quantifies a structural relationship between (i) the one atom and (ii) one or more other atoms of the plurality of atoms forming the supercell. The reverse MLM may be implemented as a convolutional neural network.

### RELATED APPLICATIONS

This application claims priority to U.S. Provisional Patent Application No. 63/627,297, filed on Jan. 31, 2024, which is incorporated herein by reference in its entirety.

### STATEMENT REGARDING FEDERALLY SPONSORED RESEARCH OR DEVELOPMENT

This invention was made with government support under grant number OAC 1940231, awarded by the National Science Foundation, and grant number HR0011-16-2-0043, awarded by the Defense Advanced Research Projects Agency (DARPA). The government has certain rights in the invention.

### BACKGROUND

The atomic environments of semiconductor heterostructures can be highly varied as various structural imperfections, lattice mismatch and non-uniform strain environments are generally present. The computational costs of first-principles modeling techniques make it challenging to fully explore how atomic environments tune the electronic bands of heterostructures.

### SUMMARY

The present embodiments include a machine-learning (ML)-assisted first-principles modeling framework that establishes a direct relationship between the atomic environments and electronic bands of semiconductor heterostructures. In some embodiments, the framework includes a forward machine-learning model (MLM) that predicts how the atomic environments tune electronic bands. In other embodiments, the framework includes a reverse MLM that extracts information about the atomic environments that is associated with an input image of a band structure of spectral function, such as those obtained with angle-resolved photoemission spectroscopy (ARPES). In yet other embodiments, the framework combines the forward MLM with the reverse MLM.

The present embodiments advantageously provide a physics-informed approach to designing heterostructures for new phenomena and device possibilities for diverse technologies.

In embodiments, a method for determining atomic structure uses a machine-learning model (MLM) that is trained to transform images of spectral functions into atomic descriptors that describe a semiconductor heterostructure, superlattice, or bulk material. The method includes feeding, into the trained MLM, an image of a spectral function of a semiconductor heterostructure. The trained MLM, in response to being fed the image, outputs a set of atomic descriptors for one atom of a plurality of atoms forming a supercell of the semiconductor heterostructure. The set of atomic descriptors include an elemental descriptor that identifies an element type of the one atom. The set of atomic descriptors also include structural descriptors, each of which quantifies a structural relationship between (i) the one atom and (ii) one or more other atoms of the plurality of atoms forming the supercell. The MLM may be implemented, for example, as a convolutional neural network (CNN), another type of artificial neural network, or another type of machine-learning model.

In some embodiments, the image of the spectral function inputted to the trained MLM is an image of a measured spectrum (i.e., data). The method may further include measuring a sample of the semiconductor heterostructure to obtain the measured spectrum. For example, the measured spectrum may be obtained by performing ARPES on the sample. In these embodiments, the method may further include fabricating the sample.

In other embodiments, the method may further include fabricating the semiconductor heterostructure based at least in part on the outputted set of atomic descriptors. The method may further include measuring this fabricated sample (e.g., via ARPES). The method may further include constructing, based on the set of atomic descriptors, a molecular or atomic structural model of the supercell of the semiconductor heterostructure. The method may further include displaying, on a screen, at least a portion of the molecular or atomic structural model.

### BRIEF DESCRIPTION OF THE FIGURES

FIG. 1A shows a forward machine-learning model (MLM) that relates atomic descriptors of semiconductor heterostructures to atomically resolved spectral functions, in embodiments.

FIGS. 1B and 1C illustrate training of the forward MLM of FIG. 1A, in embodiments.

FIG. 1D illustrates testing of the forward MLM of FIG. 1A, in embodiments.

FIGS. 2A-2F illustrate relationships between atomic descriptors and spectral functions of relaxed bulk silicon (FIG. 2A), strained bulk silicon (FIG. 2B), relaxed bulk germanium (FIG. 2C), strained bulk germanium (FIG. 2D), inner silicon atoms and interface silicon atoms of Si₂₆Ge₂₆ (FIG. 2E), inner silicon atoms and interface silicon atoms of Si₁₂Ge₁₂ (FIG. 2F), inner silicon atoms and interface silicon atoms of Si₆Ge₆ (FIG. 2G), and inner silicon atoms and interface silicon atoms of Si₄Ge₄ (FIG. 2H).

FIG. 3A shows a representative supercell of Si₈Ge₈Si₂₀Ge₂₀, with select atoms identified from the (b) Si₈ layer, (d) Si₈/Ge₈ interface, (c) Si₂₀ layer, and (e) Si₂₀/Ge₂₀ interface.

FIGS. 3B-3E show predictions made by the forward MLM of FIG. 1A for an inner silicon atom of the Si₈ layer (FIG. 3B) of the supercell of FIG. 3A, an inner silicon atom of the Si₂₀ layer (FIG. 3C) of the supercell, an interface silicon atom of the Si₈/Ge₈ interface (FIG. 3D) of the supercell, and an interface silicon atom of the Si₂₀/Ge₂₀ interface (FIG. 3E) of the supercell.

FIG. 3F shows a total spectral function (SF), DFT results, normalized intensities, and MAE for the entire supercell of FIG. 3A.

FIG. 4A shows a reverse MLM that relates atomically resolved spectral functions to atomic descriptors of semiconductor heterostructures, in embodiments.

FIGS. 4B and 4C illustrate training of the reverse MLM of FIG. 4A, in embodiments.

FIG. 4D illustrates testing of the reverse MLM of FIG. 4A, in embodiments.

FIG. 5 illustrates predictions of the reverse MLM of FIG. 4A for strain-symmetrized Si₈Ge₈Si₂₀Ge₂₀.

FIG. 6 illustrates predictions of the reverse MLM of FIG. 4A for relaxed silicon, bulk silicon, and thin-film silicon.

FIG. 7 illustrates a combined forward-reverse MLM framework that combines the forward MLM of FIG. 1A with the reverse MLM of FIG. 4A, in embodiments.

FIG. 8 illustrates generation of training supercells and selection of reference cells.

### DETAILED DESCRIPTION

Semiconductor heterostructures, or structures composed of two or more layers of dissimilar semiconductor materials, are important condensed matter systems, both for fundamental research and for device applications [1]. The remarkable advantage of these structures is that their physical properties and functionalities can be tuned by designing the constituting layers and their interfaces. However, it is crucial to understand how the atomic structures of the heterostructures influence their physical properties to exploit the full potential of these systems. The electrical, magnetic and optical properties of materials, and the response of materials to external fields are dictated by their electronic band structures. Therefore, a complete understanding of how the electronic bands of semiconductor heterostructures are influenced by their atomic structures is essential to tune their physical properties. The atomic structures of heterostructures can be highly varied as various structural imperfections and non-uniform strain environments are generally present [2-4]. These variations of the atomic structures strongly affect the electronic bands. First-principles modeling techniques, such as density functional theory (DFT), have shown remarkable success in predicting the electronic bands of complex materials. It is necessary to use supercells as large as is feasible to include the structural complexities of heterostructures to reliably predict electronic bands. One main challenge has remained that most first-principles techniques require high computational costs to analyze large supercells. Thus, it has been prohibitive to use these techniques for analyzing heterostructures with all possible structural variations.

Furthermore, the fundamental nature of the electronic bands of heterostructures often remains uncertain. This is because the structural order of the heterostructure could be approximately equal to those of the constituting layers or have a mixed character dictated by the imperfections. Due to the varied structural order, the supercell bands may resemble the Bloch states of either of the constituting layers or show a mixed character. Several unfolding techniques [5-10] have been proposed that could successfully identify the effective Bloch character of supercell bands of complex materials, especially alloys [11, 12]. However, only a few studies extended the discussion to heterostructures and established a predictive approach to describe the supercell bands of heterostructures. There is no first-principles approach available that can rapidly predict the electronic bands of experimental heterostructures for given atomic structures. Conversely, given the electronic bands of fabricated samples, it is highly challenging to predict which atomic structures they correspond to using existing approaches. As a result, most current research, spanning materials design, synthesis, and characterization, follows a long and expensive trial-and-error loop, making optimization challenging and precluding a link from atomic structures to electronic bands and the resulting physical properties. Fortunately, recent advances in machine learning (ML) techniques and materials science research present us with unique opportunities to disrupt these laborious processes and establish a new reverse paradigm for materials discovery and smart design.

In this article, we present an ML-assisted first-principles modeling framework that establishes a direct relationship between the atomic environments and the associated electronic bands of semiconductor heterostructures. We implement the framework using two ML models: (1) A forward machine-learning model (MLM) that reveals the nature of the electronic bands of a heterostructure with known atomic structures. The forward MLM accepts atomic structure descriptors as input and predicts the electronic bands of the corresponding heterostructure. (2) A reverse machine-learning model that identifies the structural properties of the atomic environment of the heterostructure that is associated with a given electronic band structure. The reverse MLM accepts computed DFT band structure images as input and predicts the corresponding atomic structure descriptors. The reverse MLM can also accept images obtained with angle-resolved photoemission spectroscopy (ARPES) techniques as input and predict the corresponding structural properties. We demonstrate the forward and reverse MLMs using a class of silicon (Si)/germanium (Ge) superlattices and heterostructures. In these MLMs, a superlattice includes one Si and one Ge layer while a heterostructure includes multiple Si and Ge layers of varied thicknesses within one period of a model supercell. Both superlattice and heterostructure supercells have been chosen to be periodically extended. We choose silicon-based structures for their wide use in technological applications. However, our approach can be extended to other materials.

In recent years, ML-assisted approaches have remarkably accelerated materials design and discovery. However, these approaches are largely based on the forward process. One iterates over different atomic structures, uses various approaches to predict the properties, and compares the predicted properties with experimental data to design new materials. An expensive trial-and-error cycle is usually followed to design materials with desired properties for different technological applications. Our framework establishes a reverse paradigm for materials discovery and smart design by directly connecting experimental observations and first-principles modeling results. Large number of high-quality characterization images are now easily accessible due to advances in spectroscopy techniques. Our framework illustrates an approach to directly connect the experimental characterization images and atomic environments of materials. This connection provides an expedited route for designing materials with desired properties, bypassing the costly trial-and-error cycle. For example, the atomic environment descriptors predicted by our reverse learning model could be compared with structural characterization data. The comparison will provide guidance for the fabrication of structures with descriptors that result in desired electronic band structures. Our forward and reverse learning framework thus establishes a direct relationship between theory and experiment and facilitates the inverse design of semiconductor heterostructures with desired electronic band structures and, in turn, physical properties.

### Forward Machine-Learning Model

### Overview

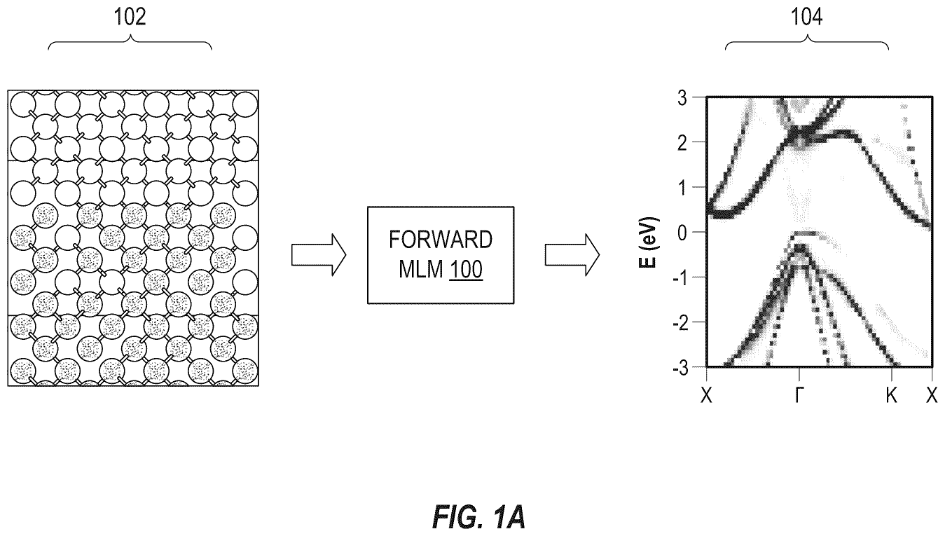

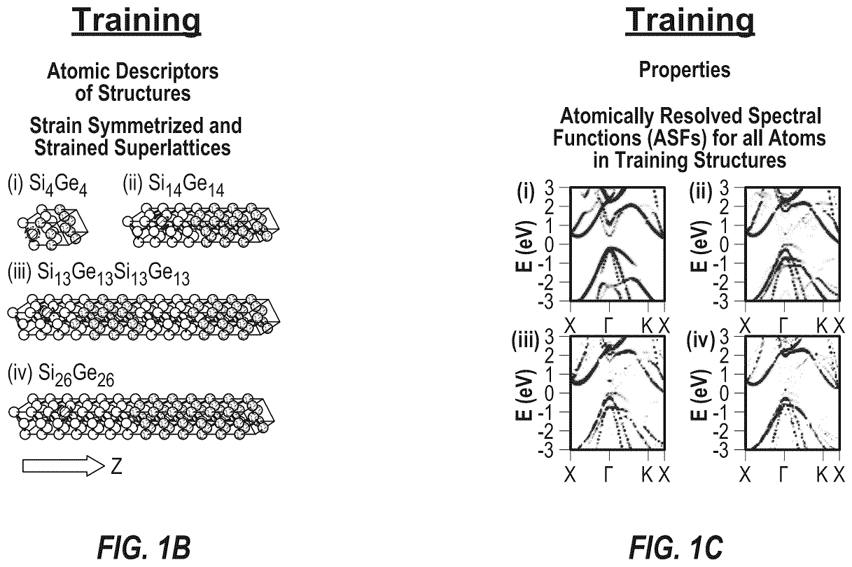

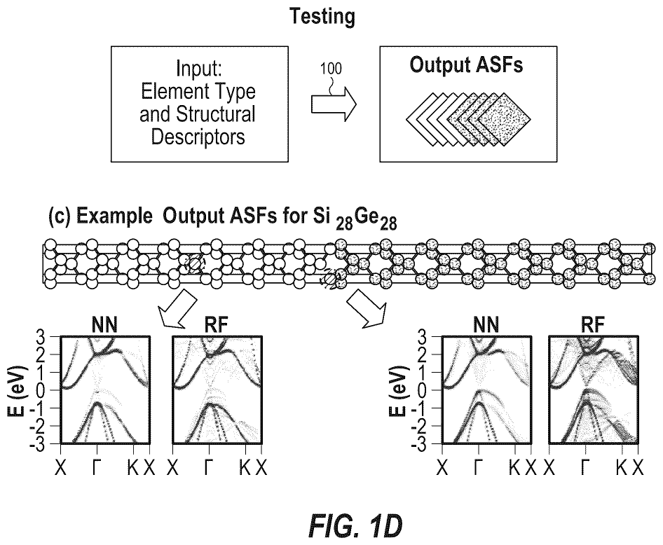

FIG. 1A illustrates a forward machine-learning model (MLM) 100, in accordance with some of the present embodiments. The forward MLM 100 receives, as input, a set of atomic descriptors that both identify and quantify various structural properties of constituent atoms forming a semiconductor heterostructure 102. The forward MLM 100 outputs an image 104 of a spectral function. The image 104 represents the spectral function as a plot of energy versus momentum. Specifically, each pixel of the image 104 represents one point of the spectral function at a corresponding value of energy and a corresponding value of momentum. The magnitude of the pixel (i.e., the value of the spectral function) is indicated by a grayscale value. As an alternative to the spectral function, the image 104 may display a band structure (e.g., an effective or unfolded band structure) of the semiconductor heterostructure 102.

For clarity in FIG. 1A, the heterostructure 102 is represented as an image of a “ball-and-stick” model that shows the relative locations and identities of the constituent atoms in real space. As an alternative to the semiconductor heterostructure 102, the forward MLM 100 may also receive, as input, descriptors for atoms forming a superlattice, a single-element crystalline material (e.g., crystalline silicon), a binary alloy (e.g., SiGe and GaAs), a ternary alloy (e.g., AlGaAs), a doped crystalline material, or any other type of condensed-matter material or system (typically a crystalline solid) that exhibits band structure.

Although not shown in FIG. 1A, the forward MLM 100 may be physically implemented on a computer system. For example, the computer system may include a processor in communication with a memory storing machine-readable instructions that, when executed by the processor, control the computer system to implement the functionality of the forward MLM 100, as described herein. Examples of the processor include, but are not limited to, a microprocessor with one or more central processing unit (CPU) cores, a graphics processing unit (GPU), and a microcontroller. Alternatively, the processor may include a field-programmable gate array (FPGA) or another type of programmable logic device that is hard-wired to implement the functionality of the forward MLM 100. The computer system may include input/output ports for communicating with additional devices (e.g., network communication, data storage, etc.). The computer system may also include a monitor or screen for displaying information. For example, the computer system may display, on the monitor, a ball-and-stick model of the semiconductor heterostructure 102. Additionally or alternatively, the computer system may display, on the monitor, the image 104 of the spectral function.

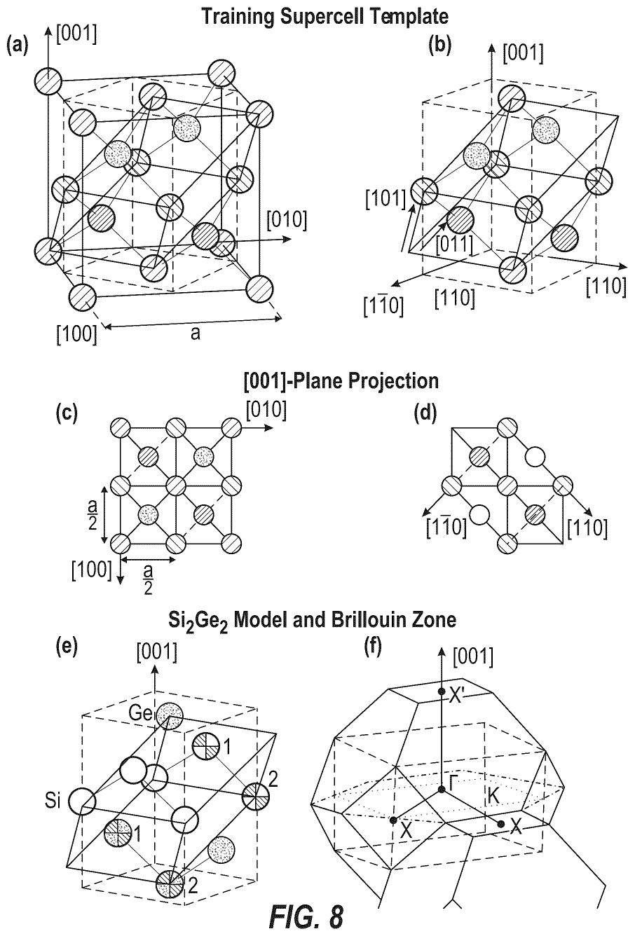

FIGS. 1B and 1C illustrate training of forward MLM 100 of FIG. 1A. The training structures include SiₙGeₙ superlattices with different periods and compositions, where the subscript n refers to the number of Si and Ge monolayers in a SiₙGeₙ superlattice. We consider both relaxed (strain-symmetrized) and strained superlattices that represent superlattices grown on substrates [13, 14]. It is well established that lattice strain strongly influences the superlattice bands [15-17] and the resulting electronic transport properties [18-23]. We include strained structures to train the ML models on band splittings due to atomic strain. Table 1 lists all training and test structures investigated in this work. We chose training structures such that the trained ML model could provide insight on diverse heterostructures used for technological applications. We model the training structures as ideal superlattices with sharp interfaces. We consider tetragonal supercells that are periodically extended in the [001] cross-plane direction (see FIG. 8). We optimize the geometry of supercells using DFT.

One aspect of the present embodiments is the realization that direct relationships exist between the atomic environments of superlattices and heterostructures and their effective band structures. We describe the atomic environments of each atom of the supercells using the type of atomic element and a set of structural features as descriptors. We compute the effective band structures (EBS) or spectral functions (SF) of the supercells using DFT. We directly compute atomically resolved band structures (AEBS) or atomically resolved spectral functions (ASFs). Plots (i)-(iv) of FIG. 1C show the ASFs corresponding to the atoms circled in the supercells (i)-(iv), respectively, shown in FIG. 1B. We train the forward MLM 100 using the two sets of data: the atomic environment descriptors of the training structures and the corresponding ASFs for each atom. The use of ASFs as training data allows us to extract large amounts of information from a limited number of training structures. ASFs not only allow us to minimize data generation efforts but also reveal fundamental insights about band dispersion in semiconductor heterostructures, as we illustrate in this article. For example, distinguishing patterns can be observed in the E−k relationships of the different ASF images shown in FIG. 1C. To test the central hypothesis, we provide descriptors of atoms of a test superlattice or heterostructure as input to the trained forward MLM and obtain the associated ASFs.

FIG. 1D shows example outputs of the forward MLM 100 for atoms of a Si₂₈Ge₂₈ superlattice. We compare the ASFs predicted by the forward MLM 100 with those computed with DFT. This superlattice structure was not included in the training set. We sum the predicted ASFs of all atoms to obtain the total SF of the test structure. Thus, we not only obtain the overall SF but also develop an understanding of how different atoms contribute to the overall SF leveraging the forward MLM.

The development of the forward learning model includes the following steps: (i) generation of training data of atomic environment descriptors, (ii) generation of training data of ASFs, (iii) implementation of ML models to identify descriptor-ASF relationships, and (iv) comparison of predicted ASFs for test structures with DFT results. In the following, we describe these steps in detail.

TABLE 1
Summary of Data Used in the Forward and Reverse Machine-Learning Framework

| | | | | |
|---|---|---|---|---|
| Structure | Training | | | Test |
| Type | Structures | Features | Properties | Structures |

Forward Learning Model: Neural Network (NN) and Random Forests (RF) Model

| | | | | |
|---|---|---|---|---|
| Strain- | Si₂ₚGe₂ₚ | Atom type: | Spectral | HS: |
| symmetrized | (p = 1, 2, . . . ,13) | 1 feature/atom | weights, | Si₈Ge₈Si₂₀Ge₂₀ |
| and strained SLs | (Si_{2q-1}Ge_{2q-1})² | Effective bond | A^{p}(k, E): | 56 atoms |
| | (q = 1, 2, . . . ,7) | lengths, bₓ & | k × E = | Input features: |
| | 5 applied strains: | b_{z}: 2 features/ | 64 × 96 = | 56 × 9 = 504 |
| | [0.00%, 0.59%, | atom | 6144 per | Output weights: |
| | 1.16%, 1.73%, 2.31%] | Order | atom (p) | 56 × 6144 = |
| | Total: 120 structures | parameters | Total | 344,064 |
| | Numbers of atoms: | Q_{x,z}^{1,2,3}: 6 | weights: | SL: Si₂₈Ge₂₈ |
| | 6 × 4 × (Σᵢ₌₁¹³Pᵢ + | features/atom | 3360 × | 56 atoms |
| | Σⱼ₌₁⁷(2_{qj} − 1)) = 3360 | Total: 3360 × | 6144 = | Input features: |
| | | 9 = 30,240 | 20,643,840 | 56 × 9 = 504 |
| | | features | | Output weights: |
| | | | | 56 × 6144 = |
| | | | | 344,064 |
| | | | | (Both strain- |
| | | | | symmetrized) |

Reverse Learning Model: Convolutional Neural Network (CNN) Model

| | | | | |
|---|---|---|---|---|
| Strain- | Same as Forward | Spectral | Atom type: | HS: |
| symmetrized | Learning Model | weights, A_{E,k}: | 1 feature/ | Si₈Ge₈Si₂₀Ge₂₀ |
| and strained SLs | | k × E = 64 × 64 | atom | strain-symmertrized |
| | | per atom | Effective | Input ASFs pixels: |
| | | Fermi level | bond lengths | 56 × 64 × 64 |
| | | alignments: | bₓ & b_{z}: | Output features: |
| | | 13 values | 2 features/ | 56 × 9 |
| | | around −0.5 to | atom | Relaxed and |
| | | +0.5 eV of | Order | strained bulk Si |
| | | mid-gap level | parameters | Other bulk Si |
| | | with step of | Q_{x,z}^{1,2,3}: | systems |
| | | 1/13 eV | 6 features/ | ARPES Si thin film |
| | | Total: | atom | For the above three |
| | | 3360 × 13 × | Total | cases |
| | | 64 × 64 = | 3360 × 9 = | Input ASFs pixels: |
| | | 43,680 × | 30,240 | 64 × 64 |
| | | [symbol] | features | Output features: 9 |
| | | images | | |
| | | 64 × 64 | | |
| | | [symbol] | | |
| | | pixels | | |

(Si_{2q-1}Ge_{2q-1})² ≡ Si_{2q-1}Ge_{2q-1}Si_{2q-1}Ge_{2q-1} for odd q = 1, 2, . . . ,7
SL: Superlattice; HS: Heterostructure;
Combined Forward-Reverse Learning Framework: NN, RF & CNN
Relaxed and 1.73% strained bulk Si
CNN Model: Input pixels: 64 × 64; Output features: 9
NN and RF Model: Input features: 9; Output weights: 64 × 96
Si ARPES spectra
CNN Model: Input pixels: 64 × 64; Output features: 9
NN And RF Model: Input features: 9; Output weights: 64 × 96

### Generation of Training Data: Descriptors

The success of ML approaches for the prediction of materials properties is crucially dependent on the selection of descriptors that can establish relevant structure-property relationships [24, 25]. In our previous study, we identified a set of descriptors of semiconductor superlattice structures that have direct relationship with their electronic transport properties [22]. We trained a random forests (RF) model and analyzed the top 35 most important features of the training structures that influenced the predictions. We noticed that the elemental property features [24] minimally affect the RF predictions of the electronic transport properties. The elemental-property-based features differ only slightly across various binary (Si/Ge) heterostructures of interest. Thus, it is reasonable to expect that they do not include sufficient information to distinguish the structure-electronic property relationships. Instead, we observed that local structural features strongly affect the predicted electronic transport properties. This observation is aligned with the understanding that electronic transport in a semiconductor heterostructure is highly sensitive to local structural environments [18-21, 26]. Based on this analysis, we used only one elemental-property feature and multiple structural features in our previous study to train our RF and neural network (NN) models. Through this strategy, our aim was to instill physics understanding in the ML models and also increase their interpretability. We showed that ML models trained with these descriptors accurately predict the electronic transport properties of semiconductor heterostructures, matching experimental data [22].

In the present study, we choose one elemental and two structural features to describe each atom X in a training or test structure. We illustrate here that these descriptors have direct relationships with superlattice electronic bands. We choose the elemental feature to be the atom type: 1 for Si and 0 for Ge. To compute the structural features, we represent each superlattice and heterostructure by crystal graphs. We perform Voronoi tessellations (VTs) and build crystal graphs by connecting the Voronoi cell of the atom X and the cells of neighboring atoms. We then use the crystal graphs and the tessellations to compute the following two structural descriptors [22]: effective bond lengths and order parameters.

The effective bond length descriptor bᵢ(X) of atom X is given by the average of the absolute distances between the atom and each of its neighbors weighted by the Voronoi cell-face areas Aₙ:

$${b}_{i} ( X ) = \frac{{\sum }_{n} {ω}_{i , n} {A}_{n} * {‖ {\vec{r}}_{n} - {\vec{r}}_{X} ‖}_{2}}{{\sum }_{n} {ω}_{i , n} {A}_{n}} . \qquad ( 1 )$$

Here, i refers to Cartesian directions (x, y, z), \vec{r}_{X} is the location of atom X, and \vec{r}ₙ and Aₙ are the location and Voronoi cell-face area of the n^{th} neighbor atom, respectively. We include the factor ω_{i,n} to define direction-dependent bond lengths: ω_{i,n} selects the projections of the face areas (Aₙ) along a chosen Cartesian direction i. \vec{ω}ₙ represents the projection of Voronoi cell face area, Aₙ, onto the Cartesian planes:

$$\begin{matrix}{\vec{ω}}_{n} = ( {ω}_{x , n} , {ω}_{y , n} , {ω}_{z , n} ) \\ = ( {cos}^{2} {ϕ}_{n} {sin}^{2} {θ}_{n} , {sin}^{2} {ϕ}_{n} {sin}^{2} {θ}_{n} , {cos}^{2} {θ}_{n} ) ,\end{matrix} \qquad ( 2 )$$

where ϕₙ and θₙ are the polar and azimuthal angles of the interatomic distance vectors between the atom X and the n^{th} neighbor. We introduce the weights \vec{ω}ₙ to describe the anisotropy of the bonding environments along the in-plane and the cross-plane directions of the superlattice. Note that bᵢ is the average neighbor distances weighed by the Voronoi cell areas projected onto the i^{th} direction. Since the areas are perpendicular to the i^{th} direction, the separation of the atoms along the perpendicular direction will affect bᵢ. For example, larger interatomic separations along the x direction will increase b_{z} and vice versa.

The order parameter descriptors measure the structural order of the atomic environments and quantify to what extent the atomic arrangement in a superlattice or heterostructure differs from purely ordered or purely random distributions [27]. We construct the order parameter descriptors by adopting a modified form of the Warren-Cowley order parameters [24, 27]. We consider crystal graphs that connect an atom X with neighboring atoms of up to order 3. We do not consider higher-order graphs since including them does not significantly affect the predictions; however, it raises the computational cost proportionally with the neighborhood volume, ˜order³. We calculate the order parameter, Qᵢ^{order}(X), of atom X by summing over the probabilities of all possible non-backtracking paths that connect atom X with neighboring atoms in a given order crystal graph:

$${Q}_{i}^{order} ( X ) {\sum }_{paths} {\prod }_{steps}^{order} \frac{{ω}_{i , n} {A}_{n} {δ}_{n X}}{{\sum }_{a} {ω}_{i , a} {A}_{a} - {\sum }_{b} {ω}_{i , b} {A}_{b}} , \qquad ( 3 )$$

where i=(x, y, z). The ratio in Eqn. 3 is the probability of taking each step on a given path. The numerator is the face area of the Voronoi cell (Aₙ) being crossed, normal to the direction of the step. The denominator is the sum over all face areas that the step could possibly cross, which are part of non-backtracking paths. The two sums in the denominator are over all allowed (a) and back-tracking (b) paths, respectively. The Kronecker delta term δ_{nX} selects only those steps that connect the atom X to neighbor n that are of the same atom types. This restriction adds species awareness to the order parameters. We include the factor ω_{i,n} to implement the directional bias as discussed before. We define directional order parameters by considering the projections of the face areas (Aₙ, Aₐ or A_{b}) along different directions separately while calculating the probabilities. We multiply the probabilities of each step on a given path to determine the probability of the selected path. The sum of the path probabilities yields the order parameters. For further details on the descriptors, see the extensive discussion in the Supplementary Information of Ref. [22].

Here, we illustrate that the chosen descriptors are highly effective in distinguishing the atomic environment of different atoms of Si/Ge superlattices. We show example descriptors of atoms of the Si₇Ge₅ superlattice in Table 2. We use a periodic supercell of the Si₇Ge₅ superlattice to compute the atomic descriptors.

TABLE 2
Descriptors of Atoms of Si₇Ge₅ Superlattice

| | Atom | Type | bₓ | b_{z} | Qₓ¹ | Q_{z}¹ | Qₓ² | Q_{z}² | Qₓ³ | Q_{z}³ |
|---|---|---|---|---|---|---|---|---|---|---|
| Si₇ | Si | 1 | 2.620 | 2.632 | 0.55 | 0.51 | 0.49 | 0.47 | 0.39 | 0.38 |
| | Si | 1 | 2.591 | 2.633 | 0.96 | 0.92 | 0.68 | 0.65 | 0.60 | 0.59 |
| | Si | 1 | 2.594 | 2.640 | 1.00 | 1.00 | 0.94 | 0.91 | 0.74 | 0.73 |
| | Si | 1 | 2.594 | 2.641 | 1.00 | 1.00 | 0.98 | 0.98 | 0.86 | 0.82 |
| | Si | 1 | 2.594 | 2.640 | 1.00 | 1.00 | 0.94 | 0.91 | 0.74 | 0.73 |
| | Si | 1 | 2.590 | 2.633 | 0.96 | 0.92 | 0.68 | 0.65 | 0.60 | 0.59 |
| | Si | 1 | 2.619 | 2.632 | 0.55 | 0.51 | 0.49 | 0.47 | 0.39 | 0.38 |
| Ge₅ | Ge | 0 | 2.686 | 2.647 | 0.53 | 0.49 | 0.46 | 0.47 | 0.36 | 0.36 |
| | Ge | 0 | 2.718 | 2.647 | 0.98 | 0.95 | 0.69 | 0.65 | 0.56 | 0.55 |
| | Ge | 0 | 2.715 | 2.638 | 1.00 | 1.00 | 0.92 | 0.88 | 0.58 | 0.51 |
| | Ge | 0 | 2.718 | 2.647 | 0.98 | 0.95 | 0.69 | 0.65 | 0.57 | 0.55 |
| | Ge | 0 | 2.687 | 2.647 | 0.53 | 0.49 | 0.46 | 0.47 | 0.36 | 0.36 |

This implies that the Si atoms of the first and seventh rows of the Si₇ layer are adjacent to a Si/Ge interface. Similarly, atoms in the eighth and twelfth rows of the Ge₅ layer are adjacent to a Ge/Si interface. The middle rows in each layer represent atoms in the inner regions of the layers. Consequently, the descriptors of each column of Table 2 show a symmetric pattern: the near-interface atoms on either side of the inner atoms have identical descriptors in the Si₇ and Ge₅ layers. However, they differ significantly from the inner atom descriptors in the respective layers. In the Si₇ layer, the bₓ values are the highest for the interface atoms and decrease as we go from the interface to the inner regions. To compensate, the b_{z} values are the lowest for the interface atoms and increase from the interface to the inner regions. An opposite trend can be observed for the atoms of the Ge₅ layer: the bₓ values are the lowest for the interface atoms. bₓ values increase while b_{z} values decrease as we move from the interface to the inner regions. Similar to the bond length descriptors, the order parameters distinguish the different atoms of the superlattice in the following way. The Q's of all order are higher for inner atoms than for the respective interface atoms. As a reference, Q's of all orders are equal to 1 for bulk systems due to the presence of neighboring atoms that are all of the same atom types. In comparison, a smaller number of atoms of the same species are present near the interfaces, resulting in a smaller number of connecting paths that contribute to the Q's. Similar reasons lead to the consistently lower values of higher-order Q's. Higher-order Q's particularly help to distinguish between different inner atoms that have the same Qᵢ¹ and Qᵢ², as can be observed from Table 2. The Q_{z} order parameters are lower than Qₓ's reflecting the heterogeneous stacking along the z direction. We only discuss the effective bond lengths and order parameters along the x and z directions, since the superlattices have similar structural environments along the in-plane x and y directions. We find that the descriptors along the x and y directions (bₓ, b_{y}) and (Q_{z}, Q_{y}¹), are identical for all atoms.

Our formulation of crystal-graph-based descriptors is conceptually analogous to contemporary graph neural network (GNN) approaches for predicting material properties [28-30], however, there are some key differences. The GNN approaches represent a molecule or a crystalline material as a graph with nodes corresponding to constituent atoms and edges corresponding to interatomic bonds. Common elemental properties (e.g., electronegativity, covalent radius, etc.) are used as node features and interatomic distances and/or bond valences as edge features. One then builds multiple layers of graph convolution that update the node features based on their local chemical environment and extract features that are strongly related to target properties. Although these approaches can be generalizable to many material classes, they require a large amount of training data to extract relevant features for predicting various properties. We also start by representing the heterostructures as crystal graphs with nodes corresponding to the constituent Si and Ge atoms. However, instead of extracting the node features using complex graph convolution, we assign the node features based on physics knowledge prior to training the model. We use one elemental property (atom type) and eight graph-derived descriptors (b_{x,z}, Q_{x,z}^{1,2,3}) as node features. Our physics-enforced approach allows us to train ML models with significantly less data; this is essential since the availability of electron transport property data for heterostructures is minimal in the large DFT databases [31, 32]. Furthermore, these descriptors help us reveal fundamental physics insights about the nature of electronic bands in semiconductor heterostructures and how they are affected by atomic environments. We identify which descriptors of the atomic environments have direct relationships with electronic bands and use the knowledge to establish a forward and inverse relationship between atomic environments and electronic bands. We argue that our proposed descriptors will make it easier to perform follow-up computations and experiments, thereby saving time and resources for future materials discovery, such as direct-gap systems or layered materials with desired electronic transport properties. However, we agree that further work is necessary to generalize our approach to a broad class of materials.

### Generation of Training Data: Spectral Functions

The electronic bands of superlattices or heterostructures are directly accessible using electronic structure calculation methods, such as DFT. It is customary to use the periodic zone representation of supercell (SC) models that include different atomic environments for the calculations. However, in most cases, the interpretation of SC energy bands is challenging due to their complexity. The SCs of our training superlattices include a wide variety of sizes, compositions, and periods, as can be seen in FIG. 1B. The different SC sizes result in highly varied electronic band structures with different numbers of bands and different folding. It is challenging to compare the SC bands of different training structures and interpret what effects the atomic environments of different structures have on their respective electronic bands, which is the central objective of this work. Thus, even though the SC electronic bands can be readily obtained from DFT calculations, it is not advantageous to use these bands as training data for the forward learning model. The complexity and low interpretability of the SC energy bands have also been discussed in the context of random alloys [11, 12], defects [6], and different heterostructures [7, 8, 10]. The effective band structure (EBS) or spectral function (SF) approach has been shown to be highly effective in providing interpretation of SC bands for these systems [5-12]. This approach provides easily recognizable band structures that specifically highlight how atomic relaxation and the presence of structural features affect electronic bands [6, 11]. Furthermore, as discuss in more detail below, the SFs allow us to compare our results with ARPES spectra and relate modeling results and experimental observations. For these reasons, we obtain SFs by unfolding the SC bands in the extended zone representation of chosen reference cells (RCs) and use the data to train the forward learning model.

Identification of appropriate RCs is particularly challenging for us, since we consider superlattices and heterostructures of different periodicity and compositions. However, it is important to note that the RC representation can be defined and unfolding can be carried out purely in a mathematical sense even when the supercells include interfaces [10]. Based on this argument, we decide on a common reference RC that resembles the primitive cell of face-centered cubic (FCC) bulk silicon and use it for all our structures. However, the RC choice is not unique, and we would like to emphasize that the insights we develop in this study are independent of the choice of the RCs. We obtain RCs from SCs by a matrix transformation (see Eqns. 4-6). The RC lattice vectors and the corresponding BZs vary for different SCs; however, all RCs include two lattice sites. The similar-sized BZs provide a common reference for comparing the unfolded band structures of different superlattices and heterostructures investigated in this study. We provide a step-by-step discussion on how we construct the RCs in the subsection below titled “Supercells and Reference Cells” and FIG. 8.

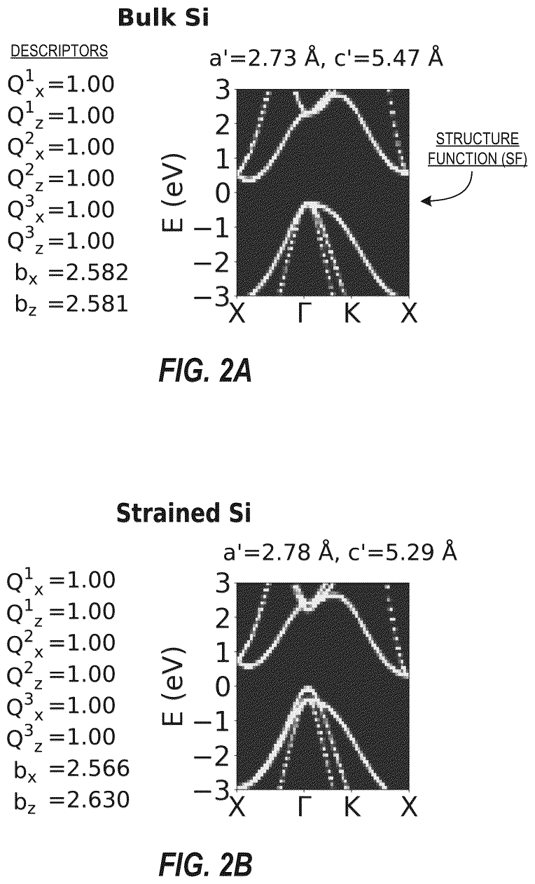

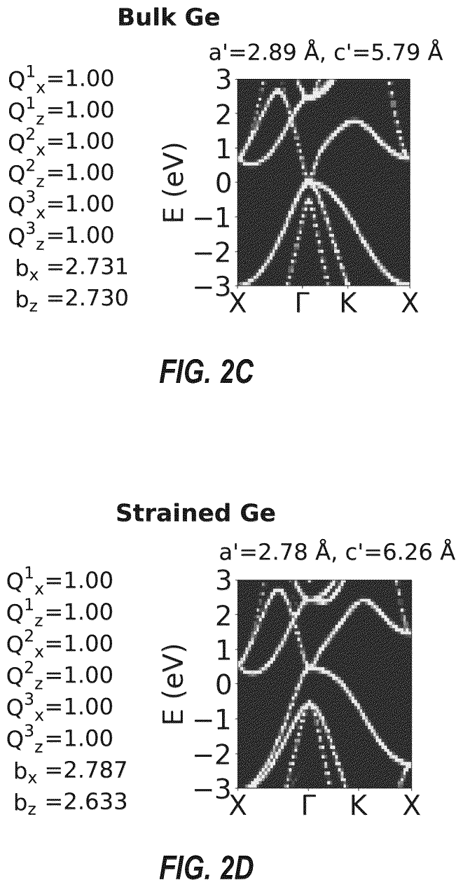

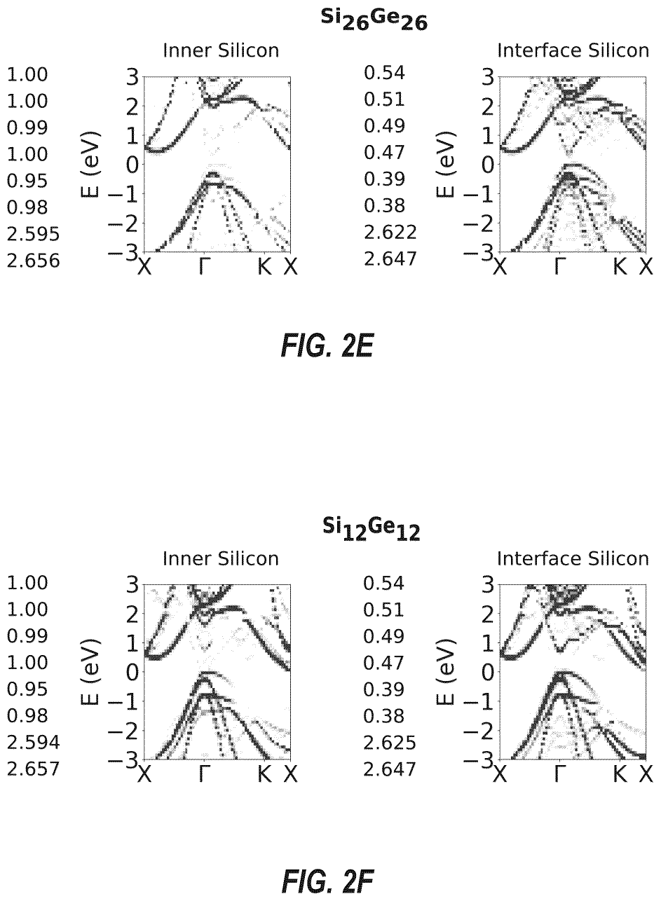

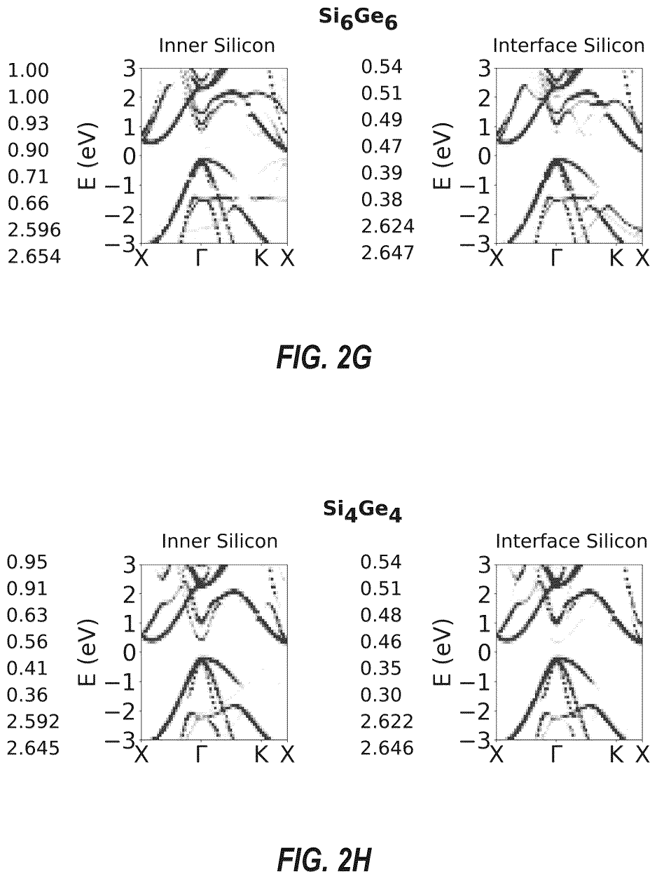

We compute the electronic bands of the superlattices and the heterostructures in the periodic zone representation of the tetragonal SCs using DFT. We perform DFT calculations using the linear combinations of atomic orbitals (LCAO) pseudopotential method, as implemented in the OpenMX package [33-36]. We use the Perdew-Burke-Ernzenhof (PBE) exchange-correlation formulation [37] of the generalized gradient approximation (GGA). We directly compute atomically resolved spectral functions (ASFs) (see the subsection below titled “Spectral Weights and Spectral Functions” for details). We compute ASFs of all atoms of the training structures along the X-Γ-K-X path shown in panel (f) of FIG. 8. We choose E=−3 to 3 eV. FIGS. 1C and 2A-2H show examples of ASFs for different training superlattices. As mentioned previously, the use of ASFs as training data allows us to extract large amounts of information from a limited number of training structures and also establish a relationship between atomic environments and band dispersion in semiconductor heterostructures, as we illustrate in the following.

### Relationship Between Descriptors and ASFs

One aspect of the present embodiments is the realization that there exists a direct relationship between the structural environments of atoms of superlattices and their corresponding ASFs. We developed the forward MLM 100 of FIG. 1A to explore this relationship, using atomic descriptors and ASF images as training data. Once trained, the forward MLM 100 predicts ASFs corresponding to the input atomic descriptors of the test structures. Here, we show the atomic descriptors and the corresponding ASFs of different superlattices in FIGS. 2A-2H to develop a qualitative understanding of the relationship. We discuss how the descriptors and ASFs vary for different superlattices and also how they deviate from the respective bulk properties.

We show the descriptors and SFs of the bulk Si and bulk Ge systems in FIGS. 2A-2D. As shown in these figures, all order parameters (Qᵢ^{order}) of the bulk systems are equal to 1, consistent with our previous discussion. The effective bond length descriptors along the x and z directions, bₓ and b_{z}, of the relaxed bulk Si (FIG. 2A) and the bulk Ge (FIG. 2C) are almost equal to each other due to cubic symmetry. We also show results for strained bulk Si and Ge models (see FIGS. 2B and 2D, respectively). As we will see in FIGS. 2E-2H, the descriptors-ASF relationships of the superlattices show behavior similar to that of the strained bulk systems. We model the strained bulk systems to mimic the experimental samples grown on a Si_{0.7}Ge_{0.3} alloy substrate. We prepare the strained bulk Si and Ge models by fixing the in-plane lattice parameter of the supercells to those of the substrate. We list the lattice parameters of the different models on top of the SF images in FIGS. 2A-2D. The lattice parameters show that the bulk Si and bulk Ge models are tensile and compressive strained, respectively, due to substrate-induced strain. FIGS. 2B and 2C show that the effective bond length descriptors change for strained bulk Si and Ge models, respectively. The descriptor bₓ is smaller (larger) than b_{z} for tensile (compressive) strained Si (Ge) models. As discussed above, larger interatomic separations along the x direction will increase b_{z} and vice versa. We observe a larger (smaller) b_{z} for the bulk Si (Ge) models with tensile (compressive) strain in the x direction, accordingly. Note that these changes in bₓ and b_{z} of the bulk systems are due to externally applied strains, while bₓ and b_{z} of the superlattices are affected by internal strain due to the lattice mismatch. The internal strain is often not easy to evaluate directly, therefore, a straightforward analysis of bₓ and b_{z} trends is not possible for superlattices. Nevertheless, the bulk results establish that the lattice strain of the atomic environments is well described by these descriptors. It is known that epitaxial strain induces splitting of the electronic bands of Si systems [38-40]. We can observe the strain-induced band splittings, especially near the Γ point, by comparing the SF images shown in FIGS. 2A and 2B.

FIGS. 2E-2H show the descriptors and ASFs of the strain-symmetrized Si/Ge superlattices Si₂₆Ge₂₆, Si₁₂Ge₁₂, Si₆Ge₆, and Si₄Ge₄, respectively. Each of these figures contains one plot showing results for atoms of the inner material and one plot showing results for atoms at the interface region. The contrasting information between the two plots in each of these figures highlights how the relationships differ for different atoms within the same superlattice.

Descriptors of Inner Atoms of Superlattices: We list the descriptors of the inner atoms of the different superlattices in FIGS. 2E-2H. The order parameters Q provide a measure of how the atomic environments differ in the inner regions of different superlattices. The order parameters Qᵢ¹ and Qᵢ² of the Si₂₆Ge₂₆ and Si₁₂Ge₁₂ superlattices are close to one while the order parameters Qᵢ³ are slightly less than one. Both of the order parameters Qᵢ² and Qᵢ³ of the Si₆Ge₆ superlattice are smaller than one. Furthermore, all of the order parameters Qᵢ¹, Qᵢ² and Qᵢ³ are smaller than one for the Si₄Ge₄ superlattice. The order parameters Q decrease systematically because the inner atom has a lower number of neighbor atoms that contribute to Q in thinner layers. The order parameters Q indicate that the inner regions of large-period superlattices are mostly “bulk-like” and the local atomic environments increasingly differ from bulk as we decrease the layer thickness. In the next paragraph, we discuss how the ASFs reflect a similar trend, supporting our hypothesis that atomic environments and ASFs are closely related. We also show the effective bond length descriptors of different superlattices in FIGS. 2E-2H. They do not change significantly for the four different superlattices. However, they describe an important aspect that the inner Si regions in all four superlattices are strained because of the larger in-plane lattice parameters of the neighboring Ge layers.

ASFs of Inner Atoms of Superlattices: FIGS. 2E-2H show the ASFs of the inner Si atoms of the different superlattices. The left plot of FIG. 2E shows the ASF of an inner Si atom of the Si₂₆Ge₂₆ superlattice. It is interesting to note that the inner Si ASF is similar to the SF image of FIG. 2A and shows a prominent bulk Si-like character. The electronic bands of Si/Ge superlattices are expected to have an average of bulk Si-like and bulk Ge-like characters [15, 21]. We indeed find that the total SFs of large-period superlattices (e.g., Si₂₆Ge₂₆, Si₂₀Ge₂₀) show a mixture of bulk Si and bulk Ge-like characters. However, the inner Si ASFs of large-period superlattices show primarily the bulk band character. This correlates with the fact that the Q-values of inner Si atoms of Si₂₆Ge₂₆ are approximately equal to one, the bulk reference value. In addition to the bulk-like character, different characteristic features are present in the inner Si ASF images that distinguish them from the bulk SFs. We discuss these features in the following.

Splitting of Bands: The inner Si ASF of the Si₂₆Ge₂₆ superlattice shows splitting of bulk-like bands: The degeneracy of the valence band maxima at the Γ point is lifted and the bands are split. The valence band splitting is similar to what can be observed in the SF image of strained Si, shown in FIG. 2B. We illustrated the strain-induced splitting of Si₄Ge₄ superlattice valence bands using first-principles studies in our previous publications [20, 21]. The lattice strain originates in superlattices because of the lattice mismatch of Si and Ge layers, as well as growth substrates. We showed that lattice strain causes the threefold degenerate states that form the bulk Si valence band maxima to split into two approximately degenerate pₓ, p_{y} states and one nondegenerate p_{z} state [15-17, 20]. The pₓ, p_{y} states form the valence-band edge in Si₄Ge₄ and the p_{z} state splits off [20]. The band splittings in all four inner Si ASF images of FIGS. 2E-2H are induced similarly by lattice strain. However, the order of the split states and the magnitude of the splitting depend on the specific atomic environments of the different superlattices. The valence band splittings become larger for Si₁₂Ge₁₂ and other short-period superlattices. The splitting of conduction bands can also be seen for short-period superlattices, especially near the Γ point. Recall that the effective bond length descriptors of FIGS. 2E-2H show that the inner Si regions in all four superlattices are strained. Hence, the presence of the strain-induced band splittings in the ASFs supports our hypothesis about the descriptor-ASF relationship.

Mixing of Bands and Avoided Crossings: As we decrease the thicknesses of the Si and Ge layers, the atomic descriptors increasingly deviate from bulk values. Correspondingly, the inner Si ASFs show a mixed Si—Ge character, as can be observed from the ASFs of the Si₆Ge₆ and the Si₄Ge₄ superlattices. The mixed character is contributed by two factors. First, the different internal strain environments in the Si and Ge layers affect the bands differently. For example, the valence band edge and the split-off states differ depending on the tensile or compressive strain in the layers. Second, the split-off bands then affect each other. Tor example, the split-off Si bands of Si₁₂Ge₁₂ and Si₆Ge₆ superlattices show a signature of avoided crossing due to the split-off Ge bands. The magnitude of the splittings is larger when the thicknesses of the Si and Ge layers are reduced, and avoided crossing is more pronounced. Avoided crossings can also be observed in the conduction bands of Si₆Ge₆ and Si₄Ge₄ superlattices, midway along X-Γ and Γ-K-X paths.

Change of Γ-Character: The mixing of bands increasingly influences the Γ-character of the ASFs as the superlattice period is reduced. The top valence band of Si₁₂Ge₁₂ superlattice displays a partial Si and a partial Ge character. The inner Si ASFs of the Si₆Ge₆ and Si₄Ge₄ superlattices also show a mixed character near the Γ point. These results demonstrate that the Γ-character of the superlattice bands strongly depends on the composition. Continuous band mixing has been demonstrated both theoretically and experimentally for alloys [41]. Here, we demonstrate the band mixing for layered heterostructured Si—Ge materials. The progression of ASF images further suggests that a direct band gap structure can be designed by tuning the composition of the heterostructures. Past studies have identified that the electronic band structure of Si₆Ge₆ superlattice has a nearly direct band gap [42] while that of Si₆Ge₄ has a direct band gap [13]. Realizing a direct band gap structure by layering two indirect band gap materials can offer various practical benefits; however, the trial-and-error process of identifying such structures can be expensive [13, 42]. FIGS. 2A-2H illustrate how the present embodiments could be used to design such a structure. Identification of the direct or indirect nature of the band gap of the Si—Ge heterostructures is out of scope for the present study because we analyze the band dispersion along a specific symmetry path.

Zone Folding: Signature of zone folded bands is visible, particularly for short-period superlattices when there is strong translational symmetry breaking. For example, the inner Si ASF of the Si₆Ge₆ superlattice (see FIG. 2G) shows a signature of folded bands along with band discontinuities. Comparing the band dispersions along X-Γ and Γ-K-X, we can observe that ASFs show more changes along the later symmetry direction. The Γ-K-X path spans two BZs as can be seen from the RC Brillouin zone presented in FIG. 8 Therefore, varied contributions are expected to result in different features. Note that RCs are mathematical constructions and may not represent true irreducible cells for a given superlattice or heterostructure. When the chosen RCs do not capture the full translational symmetry of the supercells, residual folded bands are likely to appear.

Descriptor-ASF Relationships for Interface Atoms: We show the descriptors and ASFs of the interface atoms of the different superlattices in FIGS. 2E-2H. The order parameters of the interface atoms are all much lower than one, confirming that interface environments strongly differ from bulk. It is interesting to note that the vales of the order parameters Q are approximately the same for all the different superlattices discussed here. This implies that the interface atoms are in similar environments irrespective of the composition of the superlattices. Accordingly, no clear trends can be observed from the ASFs of the interface atoms. One other aspect to note is that the interface Si ASFs resemble the inner Si ASFs for short-period superlattices (Si₆Ge₆ and Si₄Ge₄). It can be argued that the inner and interface regions cannot be clearly distinguished when the Si region is only 4 to 6 monolayers in thickness.

Here, we illustrate the direct relationship between the atomic environments and the corresponding ASFs by providing a comparative discussion of bulk Si SFs and Si ASFs of different superlattices. A similar analysis can be done using the Ge ASFs of different superlattices as well. Our analysis establishes that strain-induced band splitting, band mixing, avoided crossings, and changes of Γ-character provide a measure to differentiate the superlattice and bulk electronic bands. Quantifying these distinguishing features is critical both from the fundamental viewpoint of understanding the electronic behavior of heterostructures and for designing materials for target applications. Our forward learning model provides a direct approach to achieve both of these objectives.

### Implementation of ML Models

We implement the forward learning approach using random forests (RF) and neural network (NN) models, separately. The ML models are trained using the atomic descriptors and the ASFs of all atoms of the training structures. We provide a detailed description of the models in the Materials and Methods section below.

### Comparison of Forward MLM Predictions and DFT Results

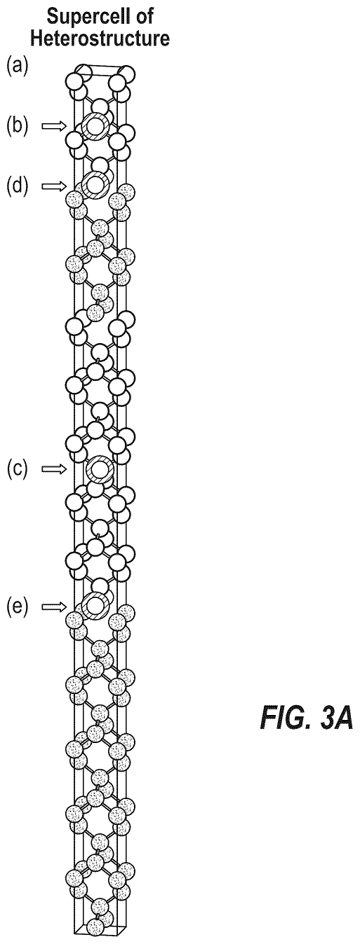

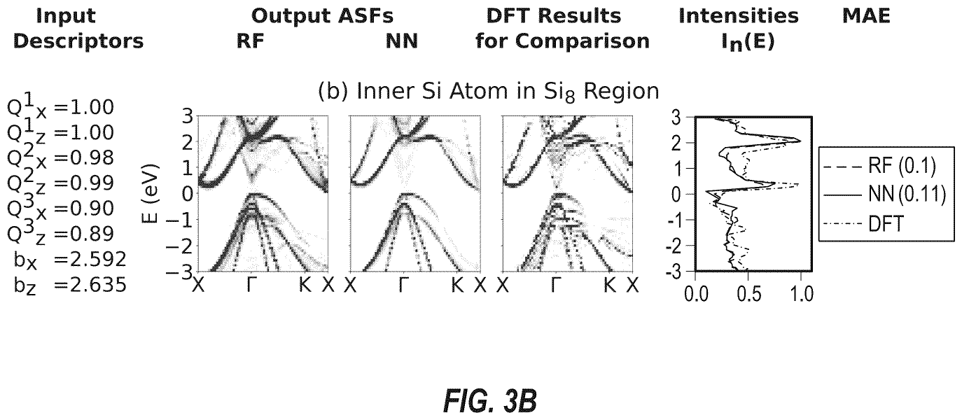

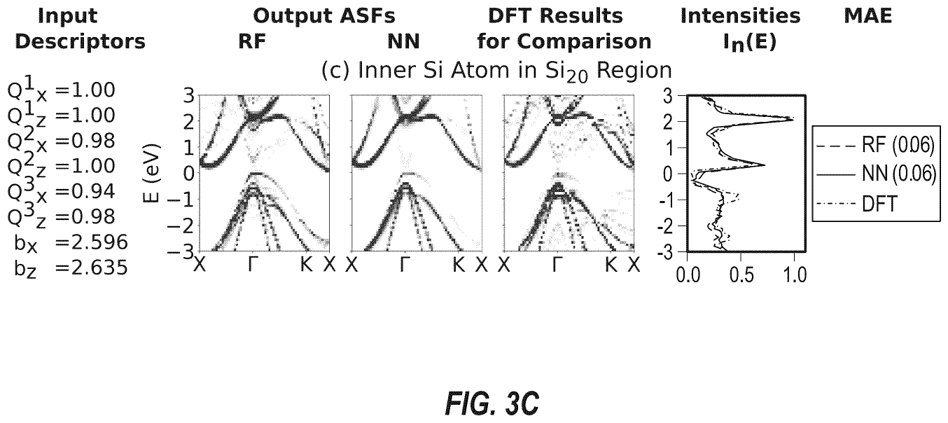

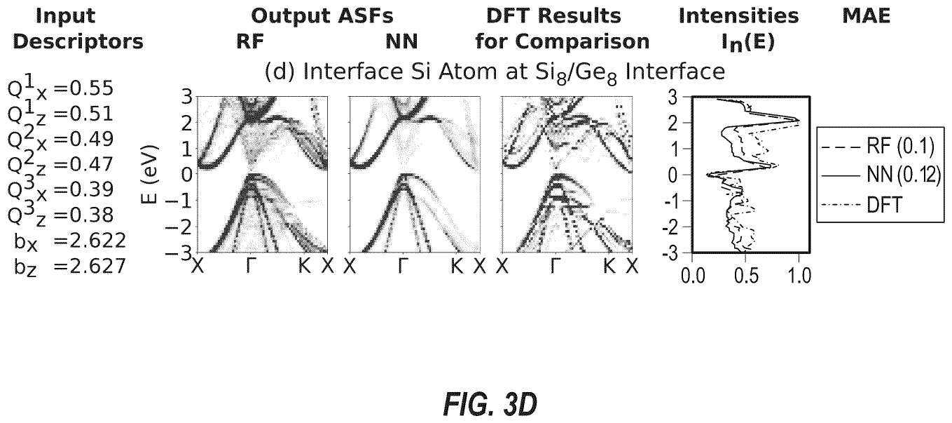

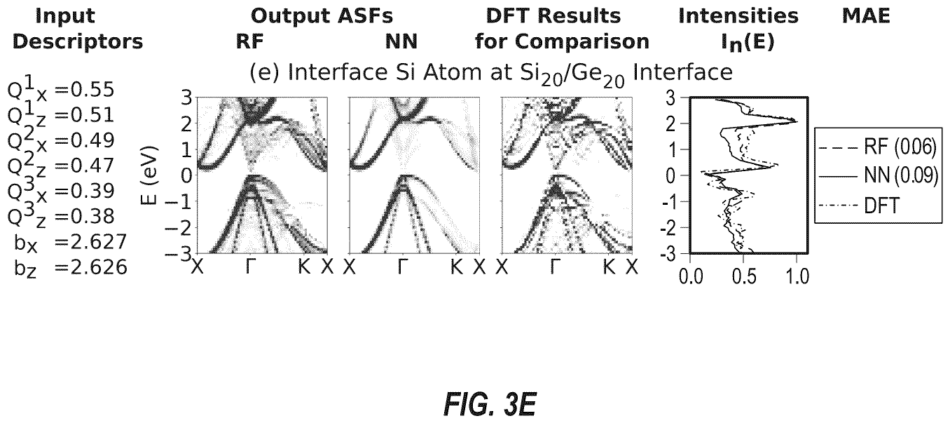

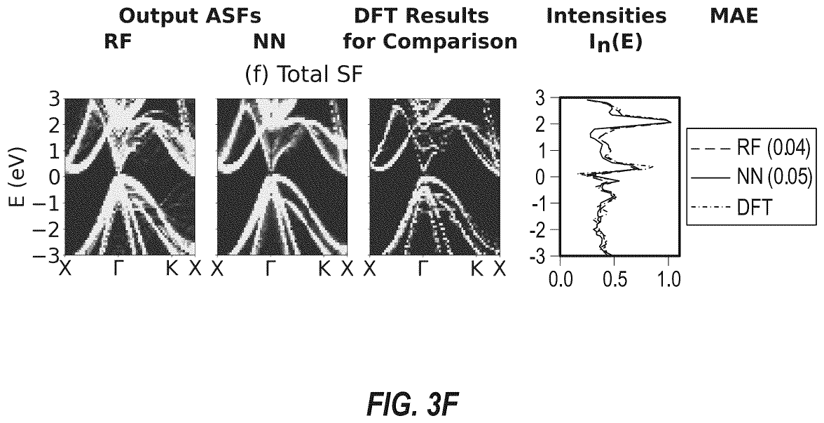

We test the performance of the forward learning model using a heterostructure and a superlattice that is not included in the training set. FIG. 3A shows the supercell of the test structure Si₈Ge₈Si₂₀Ge₂₀, which includes multiple Si and Ge layers of randomly chosen thicknesses. This configuration is likely to represent fabricated heterostructures with unevenly thick layers. We perform geometry optimization of the supercell using DFT to obtain a strain-symmetrized configuration (see the section below titled “Materials and Methods” for more details). We compute the atomic environment descriptors of all atoms and task the forward learning model to predict ASFs for input atomic descriptors. We choose four Si atoms from different regions of the supercell to illustrate the performance of the forward MLM. The chosen atoms are marked with circles in FIG. 3A. FIGS. 3B-3E show the atomic descriptors and the corresponding ASFs of the atoms marked in FIG. 3A. The first column of each panel lists the order parameters and effective bond length descriptors. The atom type feature is “1” (for Si) for all examples shown, and hence we do not include it in the list. The second and third columns show the ASFs predicted by the RF and NN forward learning models, respectively. The ASFs are predicted along the X-Γ-K-X path of the RC Brillouin zone, with k and E sampling similar to the training data. We compare the ML predictions with the respective DFT results, shown in the fourth column. Instead of comparing the ASF images, we compare the intensity, I(E) at each E, obtained by adding the ASFs at different k values. We obtain the normalized intensities by dividing I(E) by the maximum intensity: Iₙ(E)=I(E)/Max[I(E)]. We compute the mean absolute errors (MAEs) from: MAE(Iₙ,Îₙ)=Σ_{E}|Iₙ(E)−Îₙ(E)|/64. We show the comparison between predicted and computed Iₙ(E)'s in the fifth column of each panel and report the MAEs. We sum over the predicted ASFs of all atoms of the heterostructure and obtain the total SF. We show the comparison between the total SF results predicted by ML and those computed by DFT in FIG. 3F.

FIGS. 3B and 3C show the descriptors and ASFs of representative inner Si atoms of Si₈ and Si₂₀ regions of the heterostructure, respectively. The descriptors bₓ and b_{z} indicate that the atoms are in strained environments. We analyze the relative importance of all descriptors in the predictions of our RF model. We note that bₓ and b_{z} rank at the top of the list. However, as previously discussed, it is difficult to interpret the effective bond length values. Instead, we discuss the order parameters Q to obtain a qualitative understanding of the results shown in FIGS. 3A-3F. FIG. 3B shows that Qᵢ¹ and Qᵢ² of the inner Si atom of the Si₈ region are equal to or almost equal to one; however, the values of the order parameters Qᵢ³ are smaller than one. Comparatively, FIG. 3C shows that all values of the order parameters Qᵢ¹, Qᵢ² and Qᵢ³ of the inner Si atom of the Si₂₀ region are equal to or much closer to one. These values of the order parameters Q indicate that the local atomic environments in the narrow Si₈ region is less “bulk-like” compared to the inner region of Si₂₀, as can be expected. Correspondingly, the inner Si ASF of the Si₈ region exhibits a mixed Si—Ge character with large band splittings and Ge-like bands near the Γ point. The RF prediction clearly shows the mixed Si—Ge Γ character and matches the DFT results, resulting in a smaller MAE of 0.1. However, the NN model predicts a prominent bulk Si character and faint Ge-like bands near the Γ point, resulting in a slightly higher MAE: 0.11. The prediction accuracy of both models is higher (RF:0.06, NN:0.06) for the inner Si atom in the wider Si₂₀ region. The predicted inner Si ASFs show a prominent bulk Si character, corresponding to the bulk-like Q-values shown in the first column of FIG. 3C. Due to the strained atomic environment, as indicated by the descriptors bₓ and b_{z}, the ASFs also show band splitting, especially for the valence bands. The prediction accuracy establishes the ability of the forward learning model to predict the atomic environment-ASF relationships present in different heterostructure configurations. Note that the predicted inner Si₂₀ ASF is similar to the inner Si ASF of the large-period superlattice Si₂₆Ge₂₆ (see left plot in FIG. 2E). This result indicates that the inner Si atoms in Si₂₀ region are in bulk-like environments similar to the large-period superlattices. FIGS. 3D and 3E show descriptor-ASF relationships of Si atoms at the Si₈/Ge₈ and Si₂₀/Ge₂₀ interfaces, respectively. The values of the order parameters Q of both the interface atoms are similar to each other and much lower than one, similar to what is observations in FIGS. 2E-2H. Correspondingly, the interface Si ASFs are similar independent of the interfaces. Both show a mixed character and band splittings due to the varied strain environments near the interfaces. The RF predictions show an average character of the strain-split bands resulting in low errors (0.1, 0.06), while the NN model fails to capture the finer details and has higher errors (0.12, 0.09).

Although both RF and NN models predict accurate average characters, the DFT results in FIGS. 3B-3F show significantly more band splitting, mixing, and discontinuities compared to the predicted ASFs. The discrepancy can be qualitatively explained in the following way: The ML results for the different regions of the heterostructure are interpolated from ASFs of superlattices of different layer thicknesses; hence, an average character can be expected. The DFT results are not interpolated but obtained by unfolding the supercell bands in the extended zone representation of chosen RCs. It is highly likely that the RCs do not represent true irreducible cells for the given heterostructure. When the heterostructure supercell includes strongly broken translational order, the unfolded contributions from different regions may vary, resulting in broken band structures. Our training set does not include multilayer heterostructures. We expect the prediction accuracy to improve if the models are trained on such structures. Although the predicted and computed ASFs of different atoms show differences, the predicted total SFs match closely with the DFT results. The total SFs display a mixture of Si-like and Ge-like characters and have small MAEs (RF: 0.04, NN: 0.05).

### Reverse Machine-Learning Model

### Overview

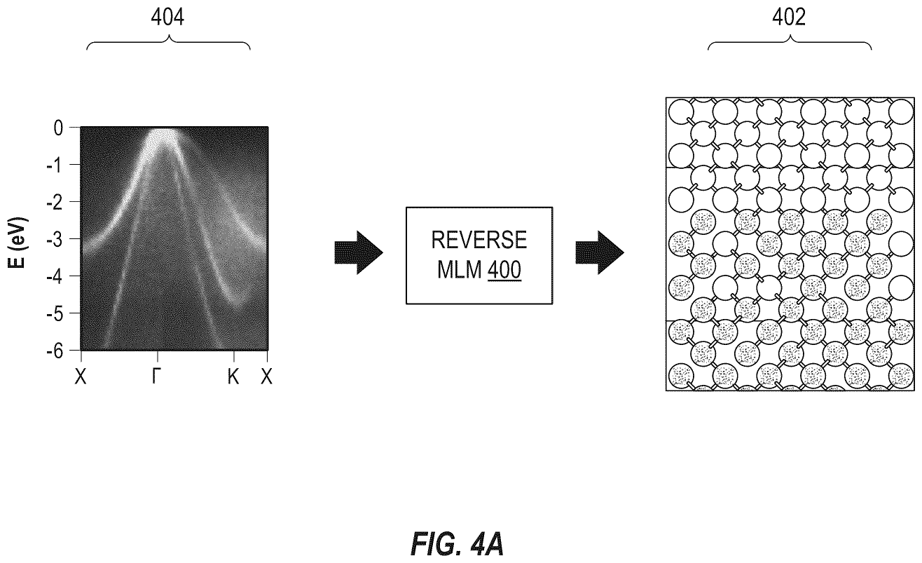

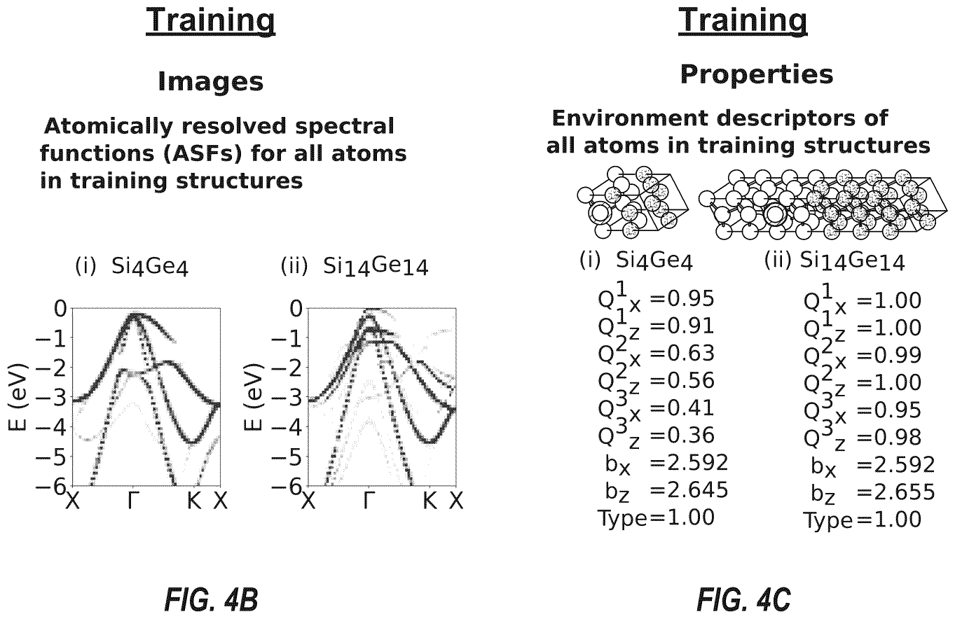

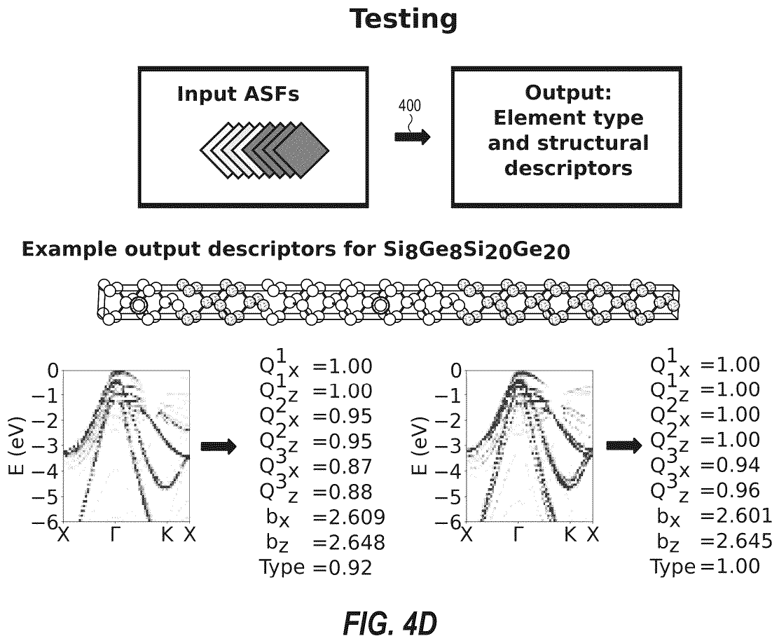

The forward MLM 100 of FIG. 1A establishes that the atomic environment of each atom of a superlattice or heterostructure has a direct relationship with an associated ASF. On the basis of the results of the forward MLM, we hypothesize that a given ASF is associated with the atomic environment in the corresponding structure. To test this hypothesis, we develop a reverse learning model (see reverse MLM 400 of FIG. 4A) that relates ASF images with the corresponding atomic environment descriptors. The reverse MLM can accept both DFT-computed ASF images and experimental images obtained with ARPES techniques as input and predict the atomic environment descriptors. Thus, our work illustrates an ML-assisted approach for interpreting ARPES images and understanding how the electronic structures of nanomaterials relate to their atomic structures. Note that we train the reverse learning model with DFT data and use the trained model to extract atomic structure information from ARPES images. We acknowledge that a direct comparison between ARPES and DFT results should be performed with caution, although both ARPES and DFT provide information on the electronic structure of materials. ARPES has the capability of directly visualizing band dispersions and Fermi surfaces by probing the energy and momentum of electrons ejected due to photoexcitation. It captures many-body effects like electron-electron interactions and electron-phonon coupling naturally, thus providing an accurate representation of the electronic structure of materials. The spectral functions obtained from DFT may not provide sufficient details of the electronic structure of strongly correlated materials and accurately represent the band gap in insulators and semiconductors. Moreover, electron lifetimes, broadening due to scattering, and band renormalization are not fully captured because DFT does not include electron-electron interaction effects. However, DFT-predicted spectral functions have been shown to match fairly well with ARPES spectra for materials with weak electron-electron correlations [43-45]. Based on these evidences, we argue that the band dispersion revealed by ARPES is equivalent to the total SFs that we discuss in this work for Si/Ge systems.

FIG. 4A illustrates a reverse MLM 400, in accordance with some of the present embodiments. The reverse MLM 400 receives, as input, an image 404 of a spectral function or energy-band diagram. The image 404 may be obtained numerically (e.g., via DFT) or experimentally (e.g., via ARPES or another type of spectroscopy). The reverse MLM 400 outputs a set of atomic descriptors that both identify and quantify various structural properties of constituent atoms forming a semiconductor heterostructure 402.

For clarity in FIG. 4A, and similar to the semiconductor heterostructure 102 depicted in FIG. 1A, the heterostructure 402 is represented as an image of a “ball-and-stick” model that shows the relative locations and identities of the constituent atoms in real space. As an alternative to the semiconductor heterostructure 402, the reverse MLM 400 may also output descriptors for atoms forming a superlattice, a single-element crystalline material, a binary alloy, a ternary alloy, a doped crystalline material, or any other type of condensed-matter material or system (typically a crystalline solid) that exhibits band structure.

Although not shown in FIG. 4A, the reverse MLM 400 may be physically implemented on a computer system. For example, the computer system may include a processor in communication with a memory storing machine-readable instructions that, when executed by the processor, control the computer system to implement the functionality of the reverse MLM 400, as described herein. Examples of the processor include, but are not limited to, a microprocessor with one or more central processing unit (CPU) cores, a graphics processing unit (GPU), and a microcontroller. Alternatively, the processor may include a field-programmable gate array (FPGA), or another type of programmable logic device, that is hard-wired to implement the functionality of the reverse MLM 400. The computer system may include input/output ports for communicating with additional devices (e.g., network communication, data storage, etc.). The computer system may also include a monitor or screen for displaying information. For example, the computer system may display, on the monitor, a ball-and-stick model of the semiconductor heterostructure 402. Additionally or alternatively, the computer system may display, on the monitor, the image 404 of the spectral function fed into the reverse MLM 400.

For the demonstrations described herein, the reverse MLM 400 of FIG. 4A is implemented as a convolutional neural network (CNN) (see the section below titled “Materials and Methods” for a detailed description of the CNN). However, a different type of machine-learning model may be used for the reverse MLM 400 without departing from the scope hereof. We trained the reverse MLM 400 with similar training structures as the forward MLM 100 of FIG. 1A (see Table 1 for details on the training data). The training data of the reverse MLM 400 includes the DFT-computed ASFs and atomic environment descriptors of all atoms in training structures. FIG. 4B shows representative ASF images of inner Si atoms in strain-symmetrized (i) Si₄Ge₄ and (ii) Si₁₄Ge₁₄ superlattices. We calculate the corresponding atomic descriptors as before, using the methods described in the section titled “Generation of Training Data: Descriptors.” FIG. 4C shows representative atomic descriptors of inner Si atoms of strain-symmetrized (i) Si₄Ge₄ and (ii) Si₁₄Ge₁₄ superlattices. We compute ASFs along the X-Γ-K-X path of the RC BZ and for the energy range of −10 eV to 10 eV. We truncate the ASFs and use only valence bands in the energy range between −6 eV to 0 eV as training data. We treat each ASF image as a grayscale image with a resolution of 64×64 pixels, with pixel intensities scaled from 0 to 1. We choose this energy range since the literature ARPES images show this range of energy values. Additionally, we account for different Fermi level alignments by applying 13 vertical shift transformations and use the generated ASF images as training data. We also postprocess the ASF images to create realistic training data. We apply Poisson and Gaussian noise and random level of gamma-correction (power transformation) to each image for gamma (power) in the range from 0.5 to 1.5 to account for various brightness levels (signal-to-noise ratios). Training the reverse learning model with these images allows us to test the model on literature images obtained from different sources, such as different numerical computations or experiments. We test the reverse learning approach by providing ASF images as input to the trained reverse MLM 400 and obtain the descriptors of the associated atomic environment. We compare the output with descriptors computed directly from structures relaxed with DFT.

### Image to Properties: Example Heterostructure

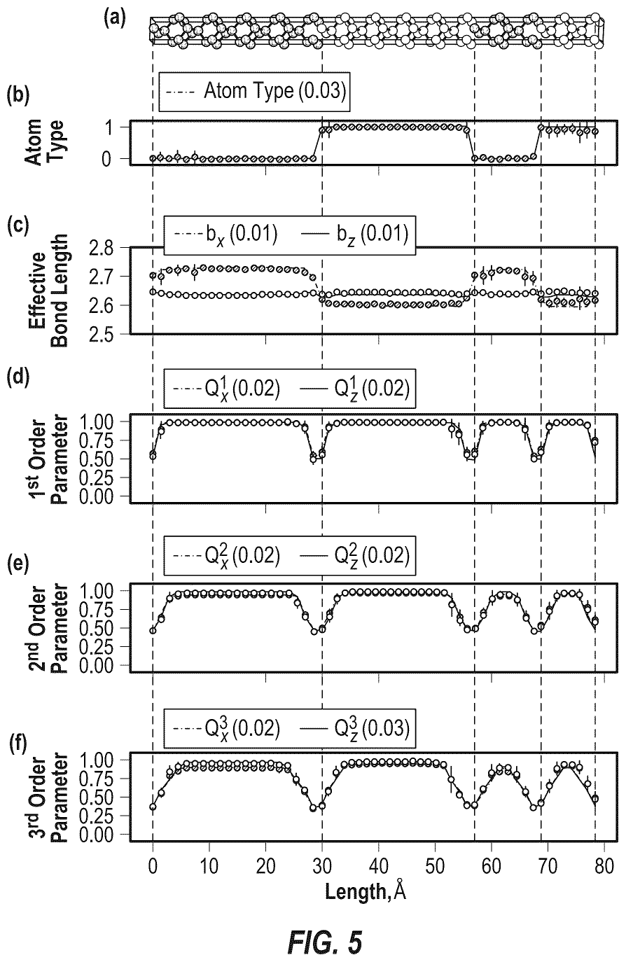

We test the performance of the reverse MLM 400 using the strain-symmetrized heterostructure Si₈Ge₈Si₂₀Ge₂₀, which includes multiple layers of Si and Ge of different thicknesses. This is the same structure used for testing the performance of the forward MLM 100. We use the trained reverse MLM 400 to predict the atomic descriptors of all atoms in the heterostructure and superlattice. Panel (a) of FIG. 5 shows the supercell of the test structure Si₈Ge₈Si₂₀Ge₂₀. Panels (b) and (c) show the CNN-predicted atom types and effective bond lengths bₓ and b_{z}. Panels (d)-(f) shows the CNN-predicted order parameters. We show the CNN model predictions with filled circles and the direct DFT-derived values with solid lines. For each atom, we create a set of unique ASF images that have different Fermi level alignments and also random noise and brightness levels applied. We test the reverse learning model by providing the set of ASF images as input and obtain multiple predictions of the descriptors. Our aim is to test whether the model is able to identify physically meaningful patterns in SF images and is not sensitive to undesired image features introduced while creating the images, such as variation of brightness, random noise of experimental setup, and inherent limitation of numerical protocol followed (e.g., DFT). The error bars reflect the standard deviation of the model predictions for the set of input ASF images. Remarkably, the error bars are small for all descriptors, indicating that the model predictions are not affected by Fermi level alignment or random features in the images. We compute the MAE for each descriptor (D) using: MAE(D,\hat{D})=Σᵢ^{p×n}|Dᵢ−\hat{D}ᵢ|/(p×n), where p is the number of atoms in the test structure and n is the number of Fermi level alignments applied (n=13).

Panels (b)-(f) of FIG. 5 show that the trained reverse MLM 400 predicts the variation of the atomic descriptors across the heterostructure with remarkable accuracy. Panel (b) of FIG. 5 shows that the atom types for inner atoms in thicker layers are predicted with a higher accuracy than interface atoms or atoms in thin layers. The results bₓ and b_{z} shown in panel (d) of FIG. 5 can be understood as follows. As discussed before, bᵢ is the average neighbor distances weighed by the Voronoi cell's areas projected onto the i direction. The Si and Ge layers have the same in-plane lattice constants, resulting in constant values of b_{z} (˜2.64 Å). However, the cross-plane monolayer separations are affected by potential perturbations [20], leading to strong variations of bₓ. The values of bₓ in Ge layers (˜2.72 Å) are higher than those in Si layers (˜2. Å), as expected. Incidentally, the effective bond length descriptors for bulk Ge and bulk Si are 2.73 Å and 2.58 Å, respectively. The slight variations can be attributed to the internal strain in the heterostructure. Panels (d)-(f) of FIG. 5 show that the order parameters of the heterostructure have a distinctive pattern consistent with our earlier discussions. All order-parameter plots clearly show the interface regions: low values of the order parameters near the interfaces indicate that the interface atoms have fewer same species neighbors. The order parameters in the inner regions of the thicker Si₂₀ and Ge₂₀ layers are almost equal to 1, indicating that the atomic environments in these regions are “bulk-like.” Plots of the order parameters Qᵢ¹ cannot distinguish the atoms in the narrow layers very well. The variation of the atomic environments in narrow layers is more clearly visible in higher-order parameter plots (Qᵢ² and Qᵢ³). FIG. 5 shows that the model accuracy is higher for bulk-like inner regions than interfaces or thinner regions. The complex character of interface ASFs (see FIGS. 3D and 3E) and the limited training data result in low-accuracy predictions. Training data for the model include ASFs that are associated with varied descriptors. The CNN model learns from these fluctuations and predicts an average result that minimizes the error over all structures in the training/validation set. It is important to note that the descriptors are calculated using Voronoi tessellations that are extremely sensitive to atomic environments and introduce uncertainty in training data and predictions [46, 47]. Despite these aspects, the remarkable results confirm that the model establishes the relationship between band structure images and the atomic structures of semiconductor heterostructures.

### Image to Properties: Bulk Silicon

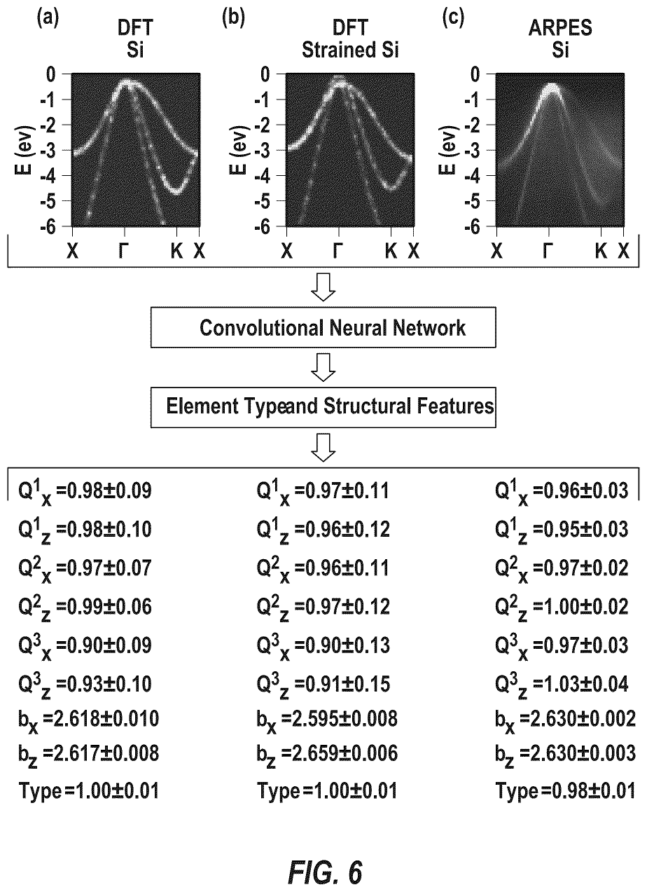

We further test the ability of our model to extract atomic structure information from images, using multiple SF images of bulk Si. Note that the model is trained only on ASF images of superlattices and not on SF images of pristine bulk Si or Ge. We use bulk Si SFs obtained from DFT as test images; the SFs and ASFs are identical for a bulk Si supercell since all atoms have identical ASFs. We compute SFs of a relaxed and a strained Si supercell using DFT. The strained Si supercell is assumed to be grown on a Si_{0.7}Ge_{0.3} alloy substrate, which induces 1.73% tensile strain along a′. FIG. 6 shows the SF images of relaxed Si (panel (a)) and strained Si (panel (b)), plotted along the X-Γ-K-X path of the bulk Si BZ. The strain-induced splitting of the valence band maxima can be noted from panel (b) of FIG. 6. This image is similar to that shown in FIG. 2B. Similar to the previous test case of the heterostructure, we create a set of test images with various Fermi level alignment and random noise. Panel (c) of FIG. 6 shows the SF image of a Si thin film obtained using ARPES. We adopt the ARPES image from FIG. 6.2 of Ref. [44]: The reference image had the ARPES spectra split into multiple panels showing different symmetry directions. We combined the different panels in one image and use that as our test image. We also apply vertical shifts to the ARPES image with small increments to generate cases for different Fermi level alignments. We list the CNN-predicted descriptors for the different panels in FIG. 6. The errors reflect the variation of predictions for input SF images with different Fermi level alignments, random noise, and brightness. For all three cases, the predicted order parameters are close to the bulk values of 1.00 and the atom type is predicted accurately to be Si. It is remarkable that the model associates the test SF images with atomic environments of bulk configurations without atomic interfaces. The model seemingly recognizes that the SF images do not show any signature of band mixing and makes predictions accordingly. For both (a) the relaxed Si DFT image and (c) the ARPES image, the trained reverse MLM 400 predicts that bₓ=b_{z} within errors, indicating that the SF images represent high symmetry environments. The descriptor b_{z} is higher than bₓ for the strained Si system with strain along a′. We consider multiple strained bulk Si systems and test the model using the DFT-computed SF images. The model accurately predicts trends associated with all the strained systems. The predicted bₓ and b_{z} values are somewhat higher than the DFT results, however, all trends are accurately reproduced. The results shown in FIG. 6 illustrate that the model is capable of extracting information about the atomic environment of the underlying structures from the SF images.

### Image to Properties: Combined Forward-Reverse Learning Framework

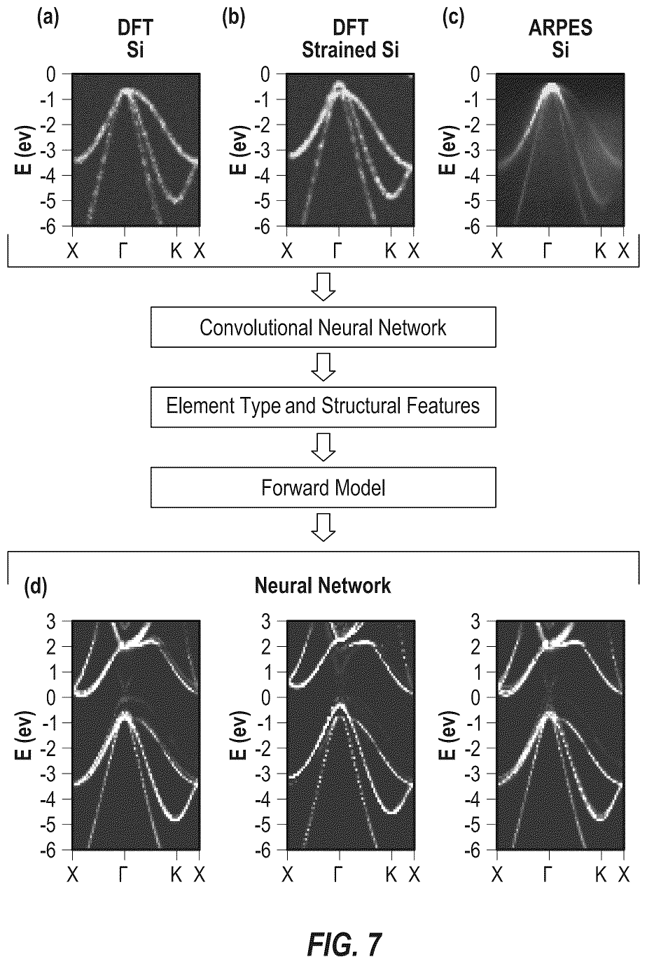

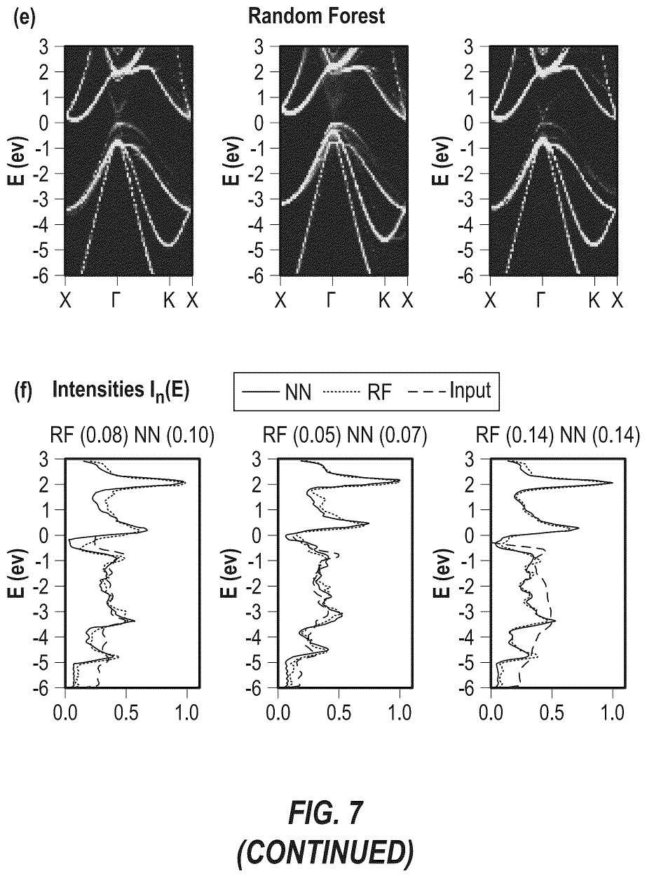

Finally, we combine forward MLM 100 of FIG. 1A and the reverse MLM 400 of FIG. 4A into one framework that can both (i) extract information on the atomic environment from test SF images and (ii) use that information to predict SFs that can be compared with test images for additional validation of the framework. We show the workflow of the combined framework in FIG. 7 using the example of the bulk Si systems discussed in FIG. 6. The CNN model reduces the input SF images to a set of atomic environment descriptors (listed in FIG. 6). We input the CNN-predicted descriptors into the forward-learning RF and NN models. Panels (d) and (e) of FIG. 7 show the corresponding SFs predicted by the forward learning model. Note that the forward learning model can predict both the conduction and the valence bands, since it is trained with DFT images that include the bands. Forward models, particularly RF, predict faint signatures of band mixing in the Γ region, since such features are present in the training data of superlattice ASF images. We compare the outputs of the combined model with the input images to validate the combined framework. We compute the normalized intensity, Iₙ(E), at each E and compute the MAEs between the predicted (Iₙ(E)) and input data (Îₙ(E)) from: MAE(Iₙ, Îₙ)=Σ_{E}|Iₙ(E)−Îₙ(E)|/64. FIG. 7F shows the comparison between normalized intensities of the input and output SF images. We find close agreement for both the DFT and ARPES bulk Si test images. The higher error in the ARPES case could be attributed to the discrepancy between the quality and brightness of the training and test images. Nevertheless, this test illustrates the remarkable ability of our framework to relate electronic bands with structural information of semiconductor systems. Our framework can be particularly beneficial for interpreting ARPES images; for example, in case of delta-doping (As or P), the Fermi level shifts and the conduction bands might not be visible in ARPES images before doping but might be afterwards [44]. Our model can be used for identifying or predicting the conduction bands in ARPES experiments for different doping.

### Discussion

The present embodiments include a ML-assisted first-principles modeling framework that establishes a direct relationship between the atomic environment and electronic bands of semiconductor heterostructures. The framework combines a forward MLM (e.g., see the forward MLM 100 of FIG. 1A) and a reverse MLM (e.g., see the reverse MLM 400 of FIG. 4A). We developed the framework to explore the relationship between the atomic environment and atomically resolved spectral functions or effective band structures of heterostructures. The forward MLM predicts how the atomic environments (e.g., neighbor bond lengths, local network of atoms, etc.) tune electronic bands of heterostructure. The model predictions establish that different atomic environments contribute differently to determine the Bloch character of heterostructure bands. For example, an inner atom contributes bulk-like character; however, an interface atom introduces complex features such as band splittings, avoided crossings, and changes of Γ-characters. Based on the insights from the forward MLM, we develop the reverse MLM that extracts information about the atomic environment that is associated with an input band structure image. It is remarkable that the model can differentiate the structures corresponding to the SF images to be bulk configurations or ones with atomic interfaces. The combined model illustrates that atomic environments can be designed to tune heterostructure bands and achieve desired electrical, magnetic and optical properties. Our framework offers a physics-informed approach to create layered materials for new phenomena and device possibilities for diverse technologies. We anticipate that our framework will be highly beneficial to a wide research community since it can be used for achieving a variety of objectives, such as: direct comparison between modeling (e.g., DFT) results and experimental (e.g., ARPES) data, (2) evaluating limitations of modeling techniques for predicting electronic bands of complex materials, (3) interpreting ARPES spectra leveraging direct comparison between modeling and experimental results, (4) analyzing contributions from different constituting layers to heterostructure bands, and (5) inverse design of direct band gap semiconductors or broadly, new materials with desired electronic, magnetic and optical properties.

### Materials and Methods

### Training and Test Structures for all ML Models

Training Structures: We consider ideal superlattices with both even and odd number of monolayers, referred to as Si₂ₚGe₂ₚ (p=1, 2, . . . , 14) and Si_{2q-1}Ge_{2q-1}Si_{2q-1}Ge_{2q-1} (q=1, 2, . . . , 7), respectively. The total number of atoms in model supercells (SCs) of these superlattices are even multiples of four. The SCs of Si₂ₚGe₂ₚ configurations include 4p atoms and Si_{2q-1}Ge_{2q-1}Si_{2q-1}Ge_{2q-1} configurations have 4(2q−1) atoms. We construct the SCs using a template that includes four atomic positions, as we discuss below. For the superlattices with odd number of monolayers, we double the SC sizes to account for the structure periodicity. We consider both strain symmetrized superlattices and superlattices with applied strains: 0.00%, 0.59%, 1.16%, 1.73%, and 2.31%. The strains are measured relative to bulk Si lattice constant: ((a′−a_{Si})/a_{Si})×100, where a_{Si}=5.47 Å. The applied in-plane strain values correspond to alloy growth substrates, Si₁₋ₓGeₓ, with varied Ge concentrations: x=0, 0.1, 0.2, 0.3, 0.4.

Test Structures for Forward ML Model: Strain-symmetrized (i) Si₈Ge₈Si₂₀Ge₂₀ heterostructure and (ii) Si₂₈Ge₂₈ superlattice.

Test Structure for Reverse Learning CNN Model: Strain-symmetrized (i) Si₈Ge₈Si₂₀Ge₂₀ heterostructure, (ii) Si₂₈Ge₂₈ superlattice, (iii) relaxed and strained bulk Si models and (iv) ARPES images adopted from Ref. [44].

Supercells; We generate the model SCs for all training and test superlattices and heterostructures, using a four-atom bulk Si tetragonal cell template (Si₄). The template is derived from a bulk Si cubic conventional cell. The template and the cubic cell are shown with dashed lines and solid lines in FIGS. 8A and 8B, respectively. The volume of the template is half of the volume of the cubic cell. The lattice parameters of the template are given by, a′=b′=2.73 Å and c=5.47 Å, following geometry optimization. c=5.47 Å is same as lattice constant of bulk Si cubic cell. Our values agree with previous DFT results [48]. Although, it is known that the DFT-predicted lattice constants of bulk Si are ˜1% higher than experimental values [49]. The basis vectors of the SC template are given by a′[11̅0], b′[110], and c[001]. The template is periodically extended in the [001] growth direction. The template can be used to span a bulk Si system with cubic symmetry, e.g., [001] grown superlattices, by replicating in the [110], [110] and [001] directions. This template allows us to investigate a large variety of superlattices and heterostructures, while keeping the computational expense at a minimum.

The template includes four atomic positions (see FIG. 8). Different shadings represent atomic positions residing in planes that are a/4 apart along [001]. Panels (c) and (d) of FIG. 8 show the atomic positions as viewed along the [001] direction. To create the superlattice models, we insert Si and Ge atoms in the template atomic positions. The “+” symbols show the two Si and the two Ge atoms, while the replicas are unmarked. We obtain strain-symmetrized or strained configurations by performing geometry optimization of the supercell models. To create superlattice models with longer periods, we start with [001] periodically replicated models of SC template. We insert Si and Ge atoms in the atomic positions of the replicated template. That way, the resulting SC includes the desired number of Si and Ge monolayers. A representative eight-atom Si₄Ge₄ superlattice model is shown in panel (i) of FIG. 1B.

Test Structures for Combined Model: Strain-symmetrized and strained bulk Si, modeled with Si₄ SC. The strained model is considered to be grown on Si_{0.7}Ge_{0.3} substrate, with 1.73% in-plane strain.

Test ARPES Image for Combined Model: ARPES spectra adopted from FIG. 6.2 of Ref. [44]. We combine the band dispersions along Γ-X (see FIG. 6.2(a) of Ref. [44]) and Γ-K-X paths (see FIG. 6.2(c) of Ref. [44]) into a single image. We interpolate the experimental images from the resolution provided in Ref. [44] to 64×64 pixels in size and for energy range from −6 eV to 0 eV.

### DFT Computation Details

We optimize the lattice constants and the atomic positions of training and test SC models with conjugate gradient algorithm [50]. We sample the SC BZ with 11×11×11 k-point mesh, generated by the Monkhorst-Pack scheme [51]. Although c is generally larger than a′ and b′, we use 11×11×11 k-point mesh to accommodate for ample sampling along [001]. Such sampling is particularly necessary for complex heterostructures with irregularly thick Si or Ge layers. To simulate SC under applied strain, we assign a′ and b′ to be equal to the substrate lattice constants and relax the cell shape in the cross-plane [001] direction. The DFT calculations reported in this article, are performed using the OpenMX code which is based on norm-conserving pseudopotentials generated with multiple reference energies [52] and linear combination of optimized pseudoatomic basis functions [33]. We use the Perdew-Burke-Ernzenhof exchange-correlation formulation [37] of the generalized gradient approximation. Self-consistent field (SCF) calculations are performed during the geometry optimization with energy convergence threshold set to 10⁻⁹ Hartree. The SCs are optimized until the maximum force on an atom became less than 10⁻⁴ Hartree Bohr⁻¹. We use a regular mesh of 200 Ryd in real space for the numerical integrations and solution of Poisson equation [53]. We do not include spin-orbit interaction in our analysis since strain induced band splittings were shown to be larger than the spin-orbit splittings [16]. For the silicon and germanium atoms, 2, 2, and 1 optimized radial functions were allocated for the s-, p- and d-orbitals, respectively, as denoted by s2p2d1. The one-particle wave functions are expressed by the linear combination of pseudo-atomic orbital (PAO) basis functions centered on atomic site [33, 34]. A cutoff radius of 7.0 Bohr was used for all the basis functions. Following relaxation, we perform non self-consistent field (NSCF) calculations using the linear combinations of atomic orbitals (LCAO) pseudopotential method [33, 34]. We obtain the eigenstates, |KJ [symbol] and energy, ϵ_{KJ}, for the range from −10 eV to 10 eV. Here, |KJ [symbol] represents a Bloch state with crystal momentum K and band index J, ϵ_{KJ} is the corresponding eigenvaue [54]. We use a 7×7×7 k-point mesh generated according to the Monkhorst-Pack method [51] to sample the supercell BZ. Such k-point mesh has been used in DFT studies for calculation of electronic structure of two-atom Si lattice [54].

### Supercells and Reference Cells

We unfold SC electronic band structures to the BZ of chosen reference cells (RCs) via SFs [6-9, 12, 55]. Panels (a)-(d) of FIG. 8 show a representative rhombohedron RC with solid lines. The embedding cubic conventional cell and the SC template are also shown. The volume of the RC is 1/4 the volume of the conventional cell. The RC resembles the two-atom primitive cell of FCC Si lattice. If no symmetry breaker is present in the SC, the RC will be identical to a primitive cell. We determine the RC basis vectors from SC basis vectors. In general, the SC basis vectors are given by:

$$\vec{B} = ( \begin{matrix}{a}^{′} & - {a}^{′} & 0 \\ {b}^{′} & {b}^{′} & 0 \\ 0 & 0 & {c}^{′}\end{matrix} ) , \qquad ( 4 )$$

where a′=b′ and c′ are the SC lattice parameters. The SC (B) and the RC basis vectors (b) are related via a transformation matrix, M: \vec{b}=M\vec{B}, with M given by

$$M = ( \begin{matrix}- \frac{1}{2} & \frac{1}{2} & \frac{1}{2 N} \\ \frac{1}{2} & \frac{1}{2} & \frac{1}{2 N} \\ 0 & 1 & 0\end{matrix} ) , \qquad ( 5 )$$

where N represents number of templates stacked along [001] direction in the supercell. N is equal to the total number of atoms in the SC divided by 4. For example, N=1 for Si₂Ge₂, and N=2 for Si₄Ge₄ and so on. Thus, the RC basis vectors are given by:

$$\vec{b} = ( \begin{matrix}\frac{{b}^{′} - {a}^{′}}{2} & \frac{{b}^{′} + {a}^{′}}{2} & \frac{{c}^{′}}{2 N} \\ \frac{{b}^{′} + {a}^{′}}{2} & \frac{{b}^{′} - {a}^{′}}{2} & \frac{{c}^{′}}{2 N} \\ {b}^{′} & {b}^{′} & 0\end{matrix} ) . \qquad ( 6 )$$

We obtain different basis vectors for the corresponding two-atom RCs, from the SC basis vectors a′, b′ and c′. Panel (e) of FIG. 8 shows the RC of a Si₂Ge₂ SC and panel (f) of FIG. 8 shows the corresponding BZ. We compute ASF of atoms along the path indicated by the green plane, and generate training data.

### Spectral Weights and Spectral Functions

The steps for computing SFs are as follows:
(i) Geometry optimization of chosen SCs;
(ii) Calculating SC eigenstates for a k-point mesh;
(iii) Identifying RC and a set of wave vectors {kᵢ} along a chosen path in the respective BZ;
(iv) Computing SFs for each atom along the path; and
(v) Repeating steps (i)-(iv) for a different SC.
   Below we discuss the approach used for step (iv).

In the LCAO method, a Bloch state |KJ [symbol] is expanded in the form of a linear combination of atomic basis functions |RN [symbol] as

$$\vert KJ 〉 = {\sum }_{N} {C}_{N}^{KJ} \vert KN 〉 \qquad ( 7 )$$

$$while$$

$$\vert KN 〉 = \frac{1}{\sqrt{L}} {\sum }_{R} {e}^{i K \cdot R} \vert RN 〉 . \qquad ( 8 )$$

Here, C_{N}^{KJ} are the LCAO coefficients. The atomic basis functions, |RN [symbol] , are placed in every unit cell and specified with a translational lattice vector R. N represents a symbolic orbital index, that consists of the atomic position relative to R, a multiplicity index for radial functions, an angular momentum quantum number, and a magnetic quantum number. L is the number of unit cells included in the Born-von Karman boundary condition. We unfold the SC band structures to RC BZs via SFs, Â(E), following the method proposed in Ref. [9]. It can be shown that the SF expressions in the SC and the RC representations are related via

$${A}_{kj , kj} ( E ) = {\sum }_{mnK} {S}_{mn}^{- 1} ( k ) 〈 kn \vert KJ 〉 {A}_{KJ , KJ} ( E ) 〈 KJ \vert km 〉 . \qquad ( 9 )$$

Here, |kj [symbol] is a Bloch state and m and n represent symbolic orbital indices in the RC representations. Sₘₙ(k) are the overlap matrix elements. The spectral function A_{kj,kj}(E) can be represented as a linear combination of unfolded spectral weights W_{KJ}^{k}[9]:

$${A}_{kj , kj} ( E ) = {\sum }_{K} {W}_{KJ}^{k} {A}_{KJ , KJ} ( E ) \qquad ( 10 )$$

$$with$$

$${W}_{KJ}^{k} = \frac{L}{l} {\sum }_{G} {δ}_{k - G , K} \times {\sum }_{MNr} {e}^{ik \cdot ( r - {r}^{′} ( M ) )} {C}_{M}^{KJ} {C}_{N}^{{KJ}^{*}} {S}_{0 N , rm ( M )} . \qquad ( 11 )$$

Here, L and 1 are the number of unit cells in SC and RC, respectively while r′(M) and m(M) refer to lattice vectors and orbital indices of the RC atomic basis, respectively, that correspond to the SC symbolic orbital index M. The delta function, δ_{k-G,K} signifies that W at k is contributed only by the folded Bloch state with k−G=K, where G is a reciprocal lattice vector. The spectral weights are determined by the phase factor e^{ik·(r-r′(M))}, the LCAO coefficients C_{M or N}^{KJ}, and the overlap matrix elements S_{0N,rm(M)}. In the LCAO method, we allocate same basis functions for each atomic species in the SCs with varied periods and compositions. However, same AOs contribute differently to the electronic bands of different SCs due to structural features. The influence of atomic structures is recorded in the LCAO coefficients and the overlap integrals between basis functions. It is important to note that the spectral weights are calculated in the SC representation without relying on any RC details. Thus, unfolding is performed purely in a mathematical sense and is valid as long as a RC can be defined.

Additionally, we compute the atomically resolved SFs that allow us to analyze how spectral weights vary based on the atomic environment. To obtain ASFs, we express the orbitally resolved SFs as:

$${A}_{kj , kj}^{M} ( E ) = {\sum }_{K} {A}_{KJ , KJ} ( E ) {W}_{KJM}^{k} , \qquad ( 12 )$$

where the orbitally resolved spectral weights W_{KJM}^{k} are given by

$${W}_{KJM}^{k} = \frac{L}{l} {\sum }_{G} {δ}_{k - G , K} {C}_{M}^{KJ} \times {\sum }_{Nr} {e}^{ik \cdot ( r - {r}^{′} ( M ) )} {C}_{N}^{{KJ}^{*}} {S}_{0 N , rm ( M )} \qquad ( 13 )$$

and are obtained by rearranging Eqn. 11. Equation 10 can then be written as

$${A}_{kj , kj} ( E ) = {\sum }_{M} {A}_{kj , kj}^{M} ( E ) = {\sum }_{K} {A}_{KJ , KJ} ( E ) {\sum }_{M} {W}_{KJM}^{k} . \qquad ( 14 )$$

The values of index M depend on the SC size and the number of basis functions for each atom. As an example, for a supercell with n atoms and m basis function per atom, M ranges from 1 to n×m. By decomposing the spectral weights and the SFs, it is possible to analyze the contribution from different localized basis functions to bands. We obtain the atomically resolved SFs from the orbitally resolved SFs. Considering that there are m basis functions assigned to the p^{th} atom in the supercell: {p₁, . . . , pₘ}⊂M, we add pₘ orbitally resolved spectral weights W_{KJp}_{ₘ}^{k} to obtain the ASFs for each atom. Thus, total SF can then be written as

$${A}_{kj , kj} ( E ) = {\sum }_{K} {A}_{KJ , KJ} ( E ) {\sum }_{p} {\sum }_{m ⊂ M} {W}_{{KJp}_{m}}^{k} , \qquad ( 15 )$$

or, in terms of the atomically resolved SFs A_{kj,kj}^{p}(E),

$${A}_{kj , kj} ( E ) = {\sum }_{p} {A}_{kj , kj}^{p} ( E ) = {\sum }_{p} {\sum }_{m ⊂ M} {A}_{kj , kj}^{{p}_{m}} ( E ) . \qquad ( 16 )$$

Here, A_{KJ,KJ}(E) is a delta function δ(E−ϵ_{KJ}).

We obtain the SC eigenstates (E_{KJ}) for the energy range from −10 eV to 10 eV from the NSCF calculations. We compute spectral weights by unfolding the SC eigenstates |KJ [symbol] on RC Bloch states |kᵢ [symbol] . We choose a set of 100 wave vectors {kᵢ} along the X-Γ-K-X path of the RC Brillouin zone (as depicted in FIG. 8F). We do not explicitly keep track of the band indices and drop the subscript j. The spectral weights are then convoluted with the above delta function to obtain A_{k,k}^{p}(E) or A^{p}(k, E). We model the delta function δ(E−ϵ_{KJ}) representing A_{KJ,KJ}(E) with an exponential function with width 0.02 eV. For the forward ML model, we use a 450-point sampling for the delta function between −6 eV≤E≤3 eV. We then interpolate over 300×450 values of A^{p}(k, E) and obtain 64×96 ASF values. The ASFs A^{p}(k, E) are defined over {k}→X-Γ-K-X and −6 eV≤E≤3 eV. The total SFs A(k, E) are obtained by summing over A^{P}(k, E) for all atoms in the superlattice or heterostructure. A(k, E)'s are also defined over the same k and E range with a 64×96 sampling. In the last part of this study, while comparing with the ARPES spectra, we use a 300-point sampling for −6 eV≤E≤0 eV, using a 0.02-eV-wide delta function. We choose 300 {kᵢ} vectors along X-Γ-K-X to keep a square grid for (k, E).

### ML Model Implementations

Forward Learning Approach: We implement the forward learning approach using NN and RF model, separately.

NN Model: The model has three fully-connected (dense) layers represented by the rows. The input layer with 9 input parameters is followed by two hidden layers with 16 and 32 nodes, respectively. Rectified Linear Unit (ReLU) activation functions are used for the hidden layers. The number of input parameters is equal to number of features considered, nine in our case as shown in Table 1. The output layer has 6144 nodes and linear activation function. The number of nodes in the output layer corresponds to the 64×96=6144 interpolated A^{p}(k, E) values for the respective superlattice or heterostructure. The same NN model architecture can be employed even when the size of input or output data is changed. Table 3 shows the layers, number of nodes in each layer, and activation functions of the NN model. We allocate 20% of training data for model validation. We sample random batches of size 32 sequentially from the training set (e.g., 32/3360) at each epoch during training. The last batch will be of size less than 32 if the remainder is not zero. We update the weights iteratively for 5000 epochs till the MAE between predicted and validation ASF, given by

$$MAE ( {A}^{p} , {\hat{A}}^{p} ) = \frac{{\sum }_{k , E} \vert {A}^{p} ( k , E ) - {\hat{A}}^{p} ( k , E ) \vert}{64 \times 96} , \qquad ( 17 )$$

reaches a minimum. We employ the ADAM stochastic optimization method for gradient descent [56] with a learning rate of 0.0005 to minimize the loss function (MAE in this case). The high-level NNs are implemented using the Python Keras library [57]. The optimized weights are used to predict ASF values for test structures.

RF Model: The RF model assembles results of several decision trees. Each tree is built from a random selection of training data that include both structural features and ASF of training superlattices. We use feature based decision rules to partition the training data into subsets. As an example, decision rule could be based on order parameter values, e.g., Q^{x,1} in the range 0.5-0.6, representing different atomic environments. Training data with Q^{x,1} in the range 0.5-0.6 could form a subset. The branches of the trees are constituted from the decision rules that identify features that minimize the intrasubset variation of ASF. ASF that maximizes fitting over the subset data are assigned as leaves of the tree. The tree generation process is then repeated for other random subsets of training data. We average over the predicted A^{p}(k, E) from all the trees to obtain the final predictions. We implement the RF module available in the scikit-learn Python package [58]. We use 200 regression trees per ensemble and default values for all other parameters recommended for the package. We use input and output same as the NN model, as listed in Table 3.

Reverse Learning Approach: We implement the reverse learning approach using CNN model. CNN model is extensively used for feature extraction in digital images and is able to assemble complex patterns from small training data [59]. We employ CNN to identify patterns in the training images of ASFs. The patterns of ASF images represent effects of translational symmetry breaking on the electronic bands of heterostructures. We use the CNN model to learn the relationships between these patterns and the descriptors. The model includes one coordinate channel layer (CoordinateChannel2D) [60] and three convolution layers (Conv2D), with 8, 16, and 32 filters each. Each convolution layers is followed by a max pooling layer (MaxPooling2D) and batch normalization. The dimension of the tensor at the input layer is (64, 64, 1), where the first two are the pixel dimensions of the image, and the third is the number of channels in the input image. The 64×64 pixels of A^{p}(k, E) images are provided as input. Two fully connected layers (Dense) with 16 and 32 nodes respectively with ReLU activation functions are followed by an output layer (Dense) with linear activation function. The set of descriptors outlined above are passed through the output layer.

We consider 13 different Fermi level alignments. We shift the mid-gap DFT zero energy level of the SFs of each configurations by a value dE in the range from −0.5 eV to +0.5 eV with a step of 1/13 eV. The alignments serve a role of electron doping level in ARPES experiments. This training helps the model to predict the descriptors of ARPES images with different Fermi level alignments. We allocate 20% of training data for model validation. We sample random batches of size 32 sequentially from the training set at each epoch during training. We employ the ADAM stochastic optimization method for gradient descent [56] with learning rate of 0.0005 to minimize the loss function. We update the weights iteratively for 2000 epochs till the MAE between predicted and validation descriptors reaches a minimum.

Combined Forward-Reverse Learning Model: Finally, we merge the forward and reverse trained ML models shown in Tables 3 and 4, respectively, into one combined model.

### Machine Learning Model Details

The details of the ML models are shown in Table 3 and Table 4 below.

TABLE 3
NN model for forward learning

| Layer | Nodes | Parameters |
|---|---|---|
| Dense | (16) | input dimension = |
| | | 9 features |
| | | fₐ = ReLU |
| Dense | (32) | fₐ = ReLU |
| Dense | (6144) | fₐ = Linear |

64 × 96 A^{P} (k, E)

TABLE 4
Reverse CNN block

| Layer | Shape | Parameters |
|---|---|---|
| CoordinateChannel2D | (64, 64, 4) | — |
| Conv2D | (32, 32, 8) | k = 3, s = 2 |
| | | fₐ = ReLU |
| BatchNormalization | — | — |
| Conv2D | (16, 16, 8) | k = 3, s = 2 |
| | | fₐ = ReLU |
| BatchNormalization | — | — |
| Conv2D | (8, 8, 8) | k = 3, s = 2 |
| | | fₐ = ReLU |
| BatchNormalization | — | — |
| Flatten | (512) | — |
| Dense | (16) | fₐ = ReLU |
| Dense | (8) | fₐ = ReLU |
| Dense | (n = 9 features) | fₐ = Linear |

k: kernel size,
s: stride size,
fₐ: activation function

### Figure Captions

FIGS. 1A-1D: Outline of forward learning model. FIG. 1A: a trained forward MLM 100 transforms atomic descriptors of a semiconductor heterostructure 102 into an image 104 of a spectral function of energy-band diagram. FIG. 1B: Training structures include strain-symmetrized and strained superlattices with various periods and compositions, including (i) Si₄Ge₄, (ii) Si₁₄Ge₁₄, (iii) Si₁₃Ge₁₃Si₁₃Ge₁₃ and (iv) Si₂₆Ge₂₆. Atomic environments of training structures are described using element type and structural descriptors. FIG. 1C: (i)-(iv) Property values corresponding to descriptors: atomically resolved spectral functions (ASFs) of atoms marked with circles in FIG. 1B. The trained forward MLM of FIG. 1A predicts the ASFs of atoms in a test superlattice and heterostructure that are not included in the training set. FIG. 1D: Representative test results for a Si₂₆Ge₂₆ superlattice. ASFs outputted by the trained forward MLM 100 are validated with DFT results.

FIGS. 2A-2H: Relationships between atomic descriptors and spectral functions (SFs) of Si/Ge systems investigated in this study. FIGS. 2A-2D: Descriptors and SFs of relaxed bulk Si (FIG. 2A), strained bulk Si (FIG. 2B), relaxed bulk Ge (FIG. 2C), and strained bulk Ge (FIG. 2D). FIGS. 2E-2H: Descriptors and ASFs of inner Si atoms and interface Si atoms of Si₂₆Ge₂₆ (FIG. 2E), Si₁₂Ge₁₂ (FIG. 2F), Si₆Ge₆ (FIG. 2G), and Si₄Ge₄ (FIG. 2H) superlattices.

FIGS. 3A-3F: Forward learning model predictions. FIG. 3A: representative supercell configuration of a test heterostructure with uneven layers: Si₈Ge₈Si₂₀Ge₂₀ and selected atoms from the (b) inner Si., (d) Si₈Ge₈ interface, (c) inner Si₂₀, and (e) Si₂₀Ge₂₀ interface regions of the heterostructure. FIGS. 3B-3F list atomic descriptors of chosen atoms are provided as input to the forward MLM, show output ASFs of chosen atoms predicted by the RF and NN models, show ASFs of representative atoms computed directly with DFT for comparison and validation. FIGS. 3B-3F also include comparisons between normalized intensities Iₙ(E) and MAEs for RF and NN predictions. MAEs are computed between predicted and computed values of Iₙ(E). FIG. 3F shows the total SF obtained by adding the ASFs of all atoms of the heterostructure.

FIGS. 4A-4D: Outline of reverse learning model. FIG. 4A: a trained reverse MLM 400 transforms an image 404 of a spectral function of energy-band diagram into atomic descriptors of a semiconductor heterostructure 402. FIG. 4B: Training images of example ASFs of inner Si atoms of (i) Si₄Ge₄ and (ii) Si₁₄Ge₁₄. FIG. 4C: Properties associated with training images: Element types, effective bond lengths, and order parameters. Panel (d): a trained CNN model predicts atomic descriptors for an input ASF of atoms in the heterostructure Si₈Ge₈Si₂₀Ge₂₀. Predictions are compared with descriptors computer directly via DFT.

FIG. 5: Reverse learning model predictions. Panel (a): representative supercell configuration of strain-symmetrized test heterostructure Si₈Ge₈Si₂₀Ge₂₀. Panels (b)-(f): predicted atom type, effective bond length, and spatially resolved order parameters Qᵢ^{order} (where i=(x, z) and order=1, 2, 3) for all atoms. MAEs between average predicted (circles) and calculated descriptors (solid lines) are shown in panel legends. Error bars show standard deviations of predicted values for a set of input images with different Fermi level alignments.

FIG. 6: Reverse learning model predictions. Panels (a) and (b): input images of DFT-predicted SFs for (a) relaxed and (b) strained bulk silicon. Panel (c): input image of ARPES data of thin-film silicon, adopted from Ref. [44]. The CNN predicts atomic environment descriptors for each input image. Standard deviations are calculated for images with various Fermi level alignments and artificially applied random noise.

FIG. 7: Combined forward-reverse learning framework. Panels (a)-(c): input images of DFT SFs for relaxed bulk Si (panel (a)), strained bulk Si (panel (b)), and (c) ARPES spectra of Si thin film (panel (c)) [44]. CNN extracts atomic descriptors from input. Descriptors are input to the forward learning model. Panels (d) and (e): NN output SFs (panel (d)) and RF output SFs (panel (e)) of corresponding systems. Panel (f): comparison between normalized intensities of predicted and input SF images, respectively. MAEs are shown on top of figures.

FIG. 8: Generation of training supercells (SC) and selection of reference cells (RC): Panels (a) and (b): tetragonal SC template (dashed lines) generated from a bulk Si conventional cell (solid lines). The parameter a refers to the bulk Si lattice constant. The SC template includes four atomic positions, with one position per monolayer stacked along the [001] direction. A representative two-atom RC is chosen for unfolding (solid lines). Panels (c) and (d): atomic positions in Si conventional cell, SC template, and RC viewed along the [001] direction. Panel (e): Si₂Ge₂ superlattice SC with two Si and two Ge atoms marked. Other atoms are replicas. Pairs of marked SC atoms (“1” and “2”) are mapped to the two corresponding RC atomic positions, respectively. Panel (f): SC and RC Brillouin zone (BZ). Black dashed line represents the projection of the SC BZ onto the [001] plane passing through the Γ point. Symmetry points and paths in the horizontal shaded plane are used to obtain effective band structures or spectral functions.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

### REFERENCES

[1] Z. I. Alferov, Nobel lecture: The double heterostructure concept and its applications in physics, electronics, and technology, Rev. Mod. Phys. 73, 767 (2001).
[2] D. J. Paul, Si/SiGe heterostructures: From material and physics to devices and circuits, Semicond. Sci. Technol. 19, R75 (2004).
[3] T. David, J.-N. Aqua, K. Liu, L. Favre, A. Ronda, M. Abbarchi, J.-B. Claude, and I. Berbezier, New strategies for producing defect free SiGe strained nanolayers, Sci. Rep. 8, 1 (2018).
[4] P. Chen, N. Katcho, J. Feser, W. Li, M. Glaser, O. Schmidt, D. G. Cahill, N. Mingo, and A. Rastelli, Role of surface-segregation-driven intermixing on the thermal transport through planar Si/Ge superlattices, Phys. Rev. Lett. 111, 115901 (2013).
[5] W. Ku, T. Berlijn, C.-C. Lee, et al., Unfolding first-principles band structures, Phys. Rev. Lett. 104, 216401 (2010).
[6] V. Popescu and A. Zunger, Extracting E versus \vec{k} effective band structure from supercell calculations on alloys and impurities, Phys. Rev. B 85, 085201 (2012).
[7] T. B. Boykin, N. Kharche, and G. Klimeck, Brillouin-zone unfolding of perfect supercells having nonequivalent primitive cells illustrated with a Si/Ge tight-binding parameterization, Phys. Rev. B 76, 035310 (2007).
[8] T. B. Boykin, N. Kharche, and G. Klimeck, Non-primitive rectangular cells for tight-binding electronic structure calculations, Physica E 41, 490 (2009).
[9] C.-C. Lee, Y. Yamada-Takamura, and T. Ozaki, Unfolding method for first-principles LCAO electronic structure calculations, J. Phys. Condens. Matter 25, 345501 (2013).
[10] M. Chen and M. Weinert, Layer k-projection and unfolding electronic bands at interfaces, Phys. Rev. B 98, 245421 (2018).
[11] V. Popescu and A. Zunger, Effective band structure of random alloys, Phys. Rev. Lett. 104, 236403 (2010).
[12] T. B. Boykin, N. Kharche, G. Klimeck, and M. Korkusinski, Approximate bandstructures of semiconductor alloys from tight-binding supercell calculations, J. Phys. Condens. Matter 19, 036203 (2007).
[13] M. d'Avezac, J.-W. Luo, T. Chanier, and A. Zunger, Genetic-algorithm discovery of a direct-gap and optically allowed superstructure from indirect-gap Si and Ge semiconductors, Phys. Rev. Lett. 108, 027401 (2012).
[14] L. Zhang, J.-W. Luo, A. Saraiva, B. Koiller, and A. Zunger, Genetic design of enhanced valley splitting towards a spin qubit in silicon, Nat. Commun. 4, 1 (2013).
[15] S. Satpathy, R. M. Martin, and C. G. Van de Walle, Electronic properties of the (100) (Si)/(Ge) strained-layer superlattices, Phys. Rev. B 38, 13237 (1988).
[16] M. S. Hybertsen and M. Schliiter, Theory of optical transitions in Si/Ge(001) strained-layer superlattices, Phys. Rev. B 36, 9683 (1987).
[17] C. Tserbak, H. Polatoglou, and G. Theodorou, Unified approach to the electronic structure of strained Si/Ge superlattices, Phys. Rev. B 47, 7104 (1993).
[18] V. S. Proshchenko, P. P. Dholabhai, T. C. Sterling, and S. Neogi, Heat and charge transport in bulk semiconductors with interstitial defects, Phys. Rev. B 99, 014207 (2019).
[19] V. S. Proshchenko, M. Settipalli, and S. Neogi, Optimization of Seebeck coefficients of strain-symmetrized semiconductor heterostructures, Appl. Phys. Lett. 115, 211602 (2019).
[20] V. S. Proshchenko, M. Settipalli, A. K. Pimachev, and S. Neogi, Role of substrate strain to tune energy bands-Seebeck relationship in semiconductor heterostructures, J. of Appl. Phys. 129, 025301 (2021).
[21] M. Settipalli and S. Neogi, Theoretical prediction of enhanced thermopower in n-doped Si/Ge superlattices using effective mass approximation, J. Electron. Mater. 49, 4431 (2020).
[22] A. K. Pimachev and S. Neogi, First-principles prediction of electronic transport in fabricated semiconductor heterostructures via physics-aware machine learning, npj Comput. Mater. 7, 93 (2021).
[23] M. Settipalli, V. S. Proshchenko, and S. Neogi, The effect of electron-phonon and electron-impurity scattering on the electronic transport properties of silicon/germanium superlattices, J. Mater. Chem. C 10, 7525 (2022).
[24] L. Ward, R. Liu, A. Krishna, V. I. Hegde, A. Agrawal, A. Choudhary, and C. Wolverton, Including crystal structure attributes in machine learning models of formation energies via Voronoi tessellations, Phys. Rev. B 96, 024104 (2017).
[25] L. M. Ghiringhelli, J. Vybiral, S. V. Levchenko, C. Draxl, and M. Scheffler, Big data of materials science: critical role of the descriptor, Phys. Rev. Lett. 114, 105503 (2015).
[26] F. Schäffler, High-mobility Si and Ge structures, Semicond. Sci. Tech. 12, 1515 (1997).
[27] J. Cowley, An approximate theory of order in alloys, Phys. Rev. 77, 669 (1950).
[28] T. Xie and J. C. Grossman, Crystal graph convolutional neural networks for an accurate and interpretable prediction of material properties, Phys. Rev. Lett. 120, 145301 (2018).
[29] K. Choudhary and B. DeCost, Atomistic line graph neural network for improved materials property predictions, npj Comput. Mater. 7, 185 (2021).
[30] V. Gupta, K. Choudhary, B. DeCost, F. Tavazza, C. Campbell, W. Liao, A. Choudhary, and A. Agrawal, Structure-aware graph neural network based deep transfer learning framework for enhanced predictive analytics on diverse materials datasets, npj Comput. Mater. 10, 1 (2024).
[31] A. Jain et al., Commentary: The materials project: A materials genome approach to accelerating materials innovation, APL Mater. 1, (2013).
[32] K. Choudhary et al., The joint automated repository for various integrated simulations (JARVIS) for data-driven materials design, npj Comput. Mater. 6, 173 (2020).
[33] T. Ozaki, Variationally optimized atomic orbitals for large-scale electronic structures, Phys. Rev. B 67, 155108 (2003).
[34] T. Ozaki and H. Kino, Numerical atomic basis orbitals from H to Kr, Phys. Rev. B 69, 195113 (2004).
[35] T. Ozaki and H. Kino, Efficient projector expansion for the ab initio LCAO method, Phys. Rev. B 72, 045121 (2005).
[36] T. Ozaki et al., www.openmx-square.org (2013).
[37] J. P. Perdew, K. Burke, and M. Ernzerhof, Generalized gradient approximation made simple, Phys. Rev. Lett. 77, 3865 (1996).
[38] D. Yu, Y. Zhang, and F. Liu, First-principles study of electronic properties of biaxially strained silicon: effects on charge carrier mobility, Phys. Rev. B 78, 245204 (2008).
[39] N. F. Hinsche, I. Mertig, and P. Zahn, Effect of strain on the thermoelectric properties of silicon: an ab initio study, J. Phys. Condens. Matter 23, 295502 (2011).
[40] N. Hinsche, I. Mertig, and P. Zahn, Thermoelectric transport in strained Si and Si/Ge heterostructures, J. Phys. Condens. Matter 24, 275501 (2012).
[41] T. D. Eales et al., GepxSnx alloys: Consequences of band mixing effects for the evolution of the band gap Γ-character with Sn concentration, Sci. Rep. 9, 1 (2019).
[42] S. Froyen, D. Wood, and A. Zunger, Structural and electronic properties of epitaxial thin-layer SiₙGeₙ superlattices, Phys. Rev. B 37, 6893 (1988).
[43] H. Seo, R. C. Hatch, P. Ponath, M. Choi, A. B. Posadas, and A. A. Demkov, Critical differences in the surface electronic structure of Ge(001) and Si(001): Ab initio theory and angle-resolved photoemission spectroscopy, Phys. Rev. B 89, 115318 (2014).
[44] P. C. Constantinou, Fabrication and Characterization of Metallic, Two-Dimensional Dopant δ-Layers in Silicon, Ph.D. thesis, UCL (University College London), 2021.
[45] V. N. Strocov, L. Lev, M. Kobayashi, C. Cancellieri, M.-A. Husanu, A. Chikina, N. SchrUter, X. Wang, J. A. Krieger, and Z. Salman, k-resolved electronic structure of buried heterostructure and impurity systems by soft-X-ray ARPES, J. Electron Spectros. Relat. Phenomena 236, 1 (2019).
[46] A. Leonardi, M. Leoni, M. Li, and P. Scardi, Strain in atomistic models of nanocrystalline clusters, J. Nanosci. Nanotechnol. 12, 8546 (2012).
[47] P. Garg and T. J. Rupert, Grain incompatibility determines the local structure of amorphous grain boundary complexions, Acta Mater. 244, 118599 (2023).
[48] A. Wright, Density-functional-theory calculations for the silicon vacancy, Phys. Rev. B 74, 165116 (2006).
[49] V. Semiconductor, General Properties of Si, Ge, SiGe, SiO₂ and Si₃N₄ (2002).
[50] W. H. Press, S. A. Teukolsky, W. T. Vetterling, and B. P. Flannery, Numerical Recipes in Fortran 90: Numerical Recipes in Fortran 77V. 2. Numerical Recipes in Fortran 90 (Cambridge University Press, 1996).
[51] H. J. Monkhorst and J. D. Pack, Special points for Brillouin-zone integrations, Phys. Rev. B 13, 5188 (1976).
[52] I. Morrison, D. Bylander, and L. Kleinman, Nonlocal Hermitian norm-conserving Vanderbilt pseudopotential, Phys. Rev. B 47, 6728 (1993).
[53] J. M. Soler, E. Artacho, J. D. Gale, A. Garcia, J. Junquera, P. Ordej6n, and D. Sinchez-Portal, The SIESTA method for ab initio order-n materials simulation, J. Phys. Condens. Matter 14, 2745 (2002).
[54] K. Bystrom, D. Broberg, S. Dwaraknath, K. A. Persson, and M. Asta, Pawpyseed: Perturbation-extrapolation band shifting corrections for point defect calculations, arXiv:1904.11572 (2019).
[55] Y.-T. Lee, C.-C. Lee, M. Fukuda, and T. Ozaki, Unfolding optical transition weights of impurity materials for first-principles LCAO electronic structure calculations, Phys. Rev. B 102, 075143 (2020).
[56] D. P. Kingma and J. Ba, Adam: A method for stochastic optimization, arXiv:1412.6980 (2014).
[57] F. Chollet et al., Keras, (2015).
[58] F. Pedregosa et al., Scikit-learn: Machine learning in python, JMLR 12, 2825 (2011).
[59] A. Sharma, E. Vans, D. Shigemizu, K. A. Boroevich, and T. Tsunoda, DeepInsight: A methodology to transform a non-image data to an image for convolution neural network architecture, Sci. Rep. 9, 1 (2019).
[60] R. Liu, J. Lehman, P. Molino, F. Petroski Such, E. Frank, A. Sergeev, and J. Yosinski, Aₙ intriguing failing of convolutional neural networks and the CoordConv solution, Adv. Neural Inf. Process. Syst. 31 (2018).

What is claimed is:

1. A method for determining atomic structure, comprising:
feeding, into a trained machine-learning model, an image of a spectral function of a semiconductor heterostructure;
wherein the trained machine-learning model, in response to being fed the image, outputs a set of atomic descriptors for one atom of a plurality of atoms forming a supercell of the semiconductor heterostructure, the set of atomic descriptors comprising:
an elemental descriptor that identifies an element type of the one atom; and
a plurality of structural descriptors, each of the plurality of structural descriptors quantifying a structural relationship between (i) the one atom and (ii) one or more other atoms of the plurality of atoms forming the supercell.

2. The method of claim 1, further comprising:
constructing, based on the set of atomic descriptors, a molecular or atomic structural model of the supercell of the semiconductor heterostructure; and
displaying at least a portion of the molecular or atomic structural model on a screen.

3. The method of claim 2, further comprising:
deriving a property of the semiconductor heterostructure that is based on the set of atomic descriptors; and
displaying the property on the screen with the portion of the molecular or atomic structural model.

4. The method of claim 1, wherein:
the method further comprises feeding, into the trained learning-model, a second image of a second spectral function of the semiconductor heterostructure; and
the trained machine-learning model, in response to being fed the second image, outputs a second set of atomic descriptors for a second atom of the plurality of atoms forming the supercell, the second set of atomic descriptors comprising:
a second elemental descriptor that identifies an element type of the second atom; and
a second plurality of structural descriptors, each of the second plurality of structural descriptors quantifying a structural relationship between (i) the second atom and (ii) one or more other atoms of the plurality of atoms forming the supercell.

5. The method of claim 4, further comprising:
constructing, based on the set of atomic descriptors and the second set of atomic descriptors, a molecular or atomic structural model of the supercell of the semiconductor heterostructure; and
displaying at least a portion of the molecular or atomic structural model on a screen.

6. The method of claim 1, the trained machine-learning model comprising a trained convolutional neural network.

7. The method of claim 1, the image of the spectral function comprising an image of an atomically resolved spectral function.

8. The method of claim 1, the image of the spectral function comprising an image of a band-structure plot.

9. The method of claim 1, the image of the spectral function comprising an image of a measured spectrum.

10. The method of claim 9, further comprising measuring a sample of the semiconductor heterostructure to obtain the measured spectrum.

11. The method of claim 10, wherein said measuring the sample comprises performing angle-resolved photoemission spectroscopy on the sample.

12. The method of claim 10, further comprising fabricating the sample.

13. The method of claim 1, the plurality of structural descriptors comprising one or more effective bond lengths and one or more order parameters.

14. The method of claim 1, the set of atomic descriptors comprising only the one elemental descriptor.

15. The method of claim 1, further comprising fabricating a sample of the semiconductor heterostructure based on the set of atomic descriptors.

16. The method of claim 1, the semiconductor heterostructure comprising a binary heterostructure.

17. The method of claim 16, the binary heterostructure comprising a silicon-germanium heterostructure.

18. The method of claim 1, further comprising training an untrained machine-learning model to obtain the trained machine-learning model.

19. The method of claim 1, further comprising performing density functional theory on a model of the semiconductor heterostructure that is based on the set of atomic descriptors.
